(19) United States
(12) Patent Application Publication
(10) Pub. No.: US 2012/0225411 A1
(43) Pub. Date: Sep. 6, 2012

(54) Connector Assemblage Formational for a Dermal Communication

(76) Inventor: Melinda Kathryn Puente, Fairbanks, AK (US)

(21) Appl. No.: 13/460,791

(22) Filed: Apr. 30, 2012

Related U.S. Application Data
(63) Continuation-in-part of application No. PCT/IB2010/002823, filed on Oct. 4, 2010.
Application No. PCT/IB2010/002823 is a continuation-in-part of application No. 12/321,336, filed on Jan. 21, 2009.
(60) Provisional application No. 61/484,216, filed on May 9, 2011.

(51) Int. Cl. G09B 19/00; H05K 3/00; H02G 3/00

(52) U.S. Cl. 434/224; 174/70 R; 29/829

(57) ABSTRACT

The present invention relates generally to electrochemical-electromagnetic integration for instructional compliance management with distributed systems, methods, devices incorporating an instructional game integrated with operations training and instruction execution within a compliance lifecycle in particularly, a connector assemblage using a metamaterial and an instructional game providing security training using an RFID ID card and a RFID reader integrating terahertz radiation where the connector assemblage is conformational to a dermal communication for reducing cyber stress improving depth perception skills.

This application is a continuation-in-part application of U.S. Provisional Patent Application Ser. No. 61/484,216, filed May 9, 2011, entitled, “SYSTEMS, DEVICES AND METHODS FOR SPONTANEITY-INTERFERENCE”; PCT Application Ser. No. PCT/IB2010/002823, entitled “A CONNECTOR ASSEMBLAGE CONFORMATIONAL FOR A DERMAL COMMUNICATION,” filed Oct. 4, 2010; U.S. Provisional Patent Application Ser. No. 61/333,740 filed May 11, 2010, entitled, “SYSTEMS, DEVICES AND METHODS FOR SPONTANEITY-INTERFERENCE”; U.S. Provisional Patent Application Ser. No. 61/332,793 filed May 9, 2010, entitled ““SYSTEMS, DEVICES AND METHODS FOR SPONTANEITY-INTERFERENCE”; U.S. patent application Ser. No. 12/321,336 filed Jan. 21, 2009 entitled, “TRANSFER SYSTEMS, DEVICES AND METHODS FOR MANAGING A COMPLIANCE INSTRUCTION LIFECYCLE,” which claims priority of PCT Application Ser. No. PCT/IB2008/000103, entitled “TRANSFER-TO-PRACTICE SYSTEMS, DEVICES AND METHODS FOR MANAGING A COMPLIANCE INSTRUCTION LIFECYCLE”, filed Jan. 18, 2008, now abandoned, and U.S. Provisional Patent Application Ser. No. 61/126/477 filed May 5, 2008, entitled, “TRANSFER-TO-PRACTICE SYSTEMS, DEVICES AND METHODS FOR MANAGING A COMPLIANCE INSTRUCTION LIFECYCLE,” which both claim priority of U.S. patent application Ser. No. 11/654,429 filed Jan. 17, 2007, entitled “A METHOD OF AN INSTRUCTIONAL GAME and U.S. Provisional Patent Application Ser. No. 60/759/318, entitled “AN INSTRUCTIONAL GAME PROGRAM AND METHOD” filed Jan. 17, 2006, the teachings of which are incorporated herein by reference.

### FIELD OF THE INVENTION

### Background

The present invention relates generally to electrochemical-electromagnetic integration for instructional compliance management with distributed systems, methods, devices incorporating an instructional game integrated with operations training and instruction execution within a compliance lifecycle in particularly, a connector assemblage using a metamaterial and an instructional game providing security training using an RFID ID card and a RED reader integrating terahertz radiation where the connector assemblage is conformational to a dermal communication for reducing cyber stress improving depth perception skills.

As the structure size in electronics such as integrated circuits (ICs) decreases, the practical significance of the effect of electromigration increases. Electromigration is the transport of material caused by the gradual movement of the ions in a conductor due to the in a conductor due to the momentum transfer between conducting electrons and diffusing metal atoms. The effect is important in applications where high direct current densities are used, such as in microelectronics and related structures. A significant problem is the continued unwanted results of dentritic morphologies during electromigration. A second challenge is to fill both the physical and psychological gap in applying terahertz radiation to applications where almost no naturally occurring materials are available for such applications which would utilize thermal and rotational or vibrational submillimeter molecular line emission or absorption from gases and signature gases. Using time-domain spectroscopy for capturing 2-D and 3-D images that can then be forwarded by remote servers or cloud for processing. Further applications include heterodyne semiconductors for plasma diagnostics, quantum-dot single photon and direct detectors, laser pumped photoconductors, near quantum limited receivers for measuring electron density profiles, and detectors for synchrotron radiation.

### SUMMARY

The present invention relates generally to electrochemical-electromagnetic integration for instructional compliance management with distributed systems, methods, devices incorporating an instructional game integrated with operations training and instruction execution within a compliance lifecycle in particularly, a connector assemblage using a metamaterial and an instructional game providing security training using an RFID ID card and a RFID reader integrating terahertz radiation where the connector assemblage is conformational to a dermal communication for reducing cyber stress while improving depth perception skills.

### BRIEF DESCRIPTION OF DRAWINGS

FIG. 1A is a schematic showing an overview of a dynamic transitioning system.

FIG. 2 is a block diagram of the primary components of a spontaneity-interference platform.

FIG. 3 and FIG. 4 are diagrams of processes performed by registers on information predicated by a word command at a frequency.

FIGS. 5A, 5B, 5C, 5D, and 5E, are flowchart diagrams of a transitioning user status processing at frequency interconnections.

FIG. 6 is an illustration of a kinetic cognizance design tool to predicate a plurality of frequencies.

FIG. 7 is an illustration of the upper portion of a kinetic cognizance design tool to determine a predicator relative to a cipher.

FIG. 8 is schematic of a introduction menu for a kinetic cognizance challenge.

FIG. 9 is a schematic of an embodiment for an indevice integrating the components of FIG. 2 and methods of FIG. 1 and FIG. 5A-FIG. 5E employing an electrochemical composition.

10A-FIG. 10C are schematics of embodiments for an indevice integrating the components of FIG. 2 and methods of FIG. 1 and FIG. 5A-FIG. 5E employing an electrochemical composition.

FIG. 11 are schematics of embodiments for a self-assembling indevice and self-organizing components employing an electrochemical composition with a plurality of fresnel lenses in FIG. 2, FIG. 3, FIG. 9, FIG. 10, FIG. 11, FIG. 12 implementing the methods of FIG. 2 and FIG. 5A-FIG. 5E.

FIG. 12A and FIG. 12B are illustrations of various applications for the self-assembling indevice and the self-organizing components employing an electrochemcial composition with a plurality of fresnel lenses in FIG. 2, FIG. 3, FIG. 9, FIG. 10, FIG. 11, FIG. 12 implementing the methods of FIG. 2 and FIG. 5A-FIG. 5E.

FIG. 13 is a SEM report identifying fabrication elements.

FIG. 14 is a SEM report identifying composition fabrication elements.

FIG. 15 is a SEM report identifying composition fabrication elements.

FIG. 16 is a SEM report identifying composition fabrication elements.

FIG. 17 is a SEM image identifying composition fabrication elements.

FIG. 18 is a SEM image identifying composition fabricated elements.

FIG. 19 is a SEM image identifying composition fabricated elements.

FIG. 20 is a SEM image identifying composition fabricated elements.

FIG. 21 is a conductive construction method using a printing, cutting and die-cast method for a linear actuator motor.

### DESCRIPTION TRANSITIONING ENTITY STATUS ARCHITECTURE

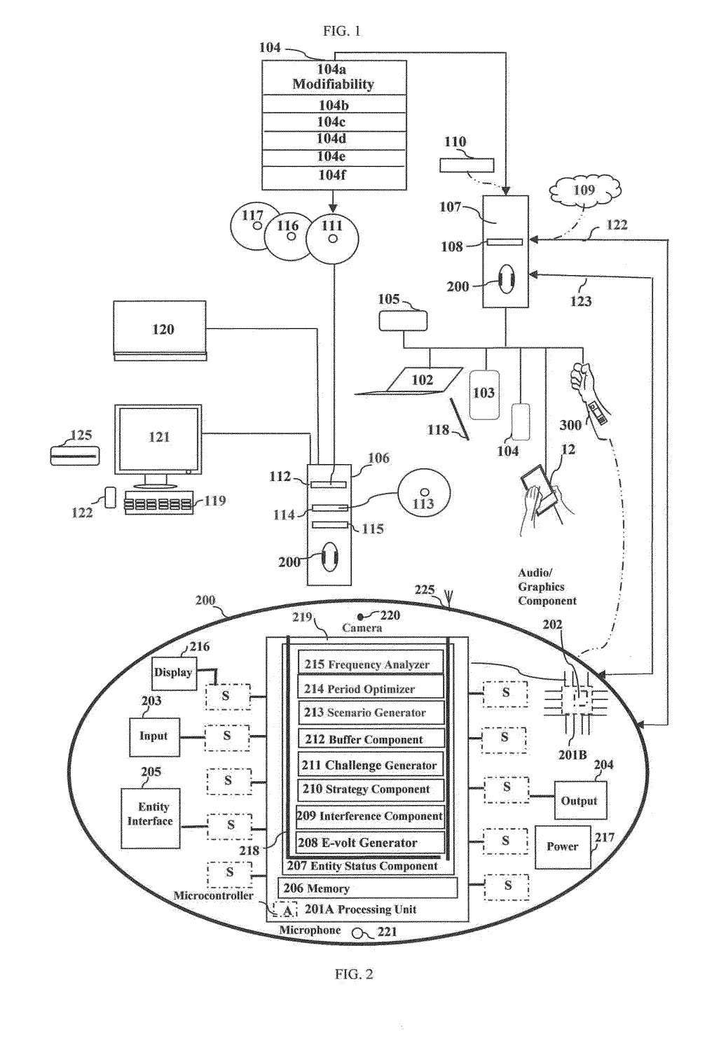

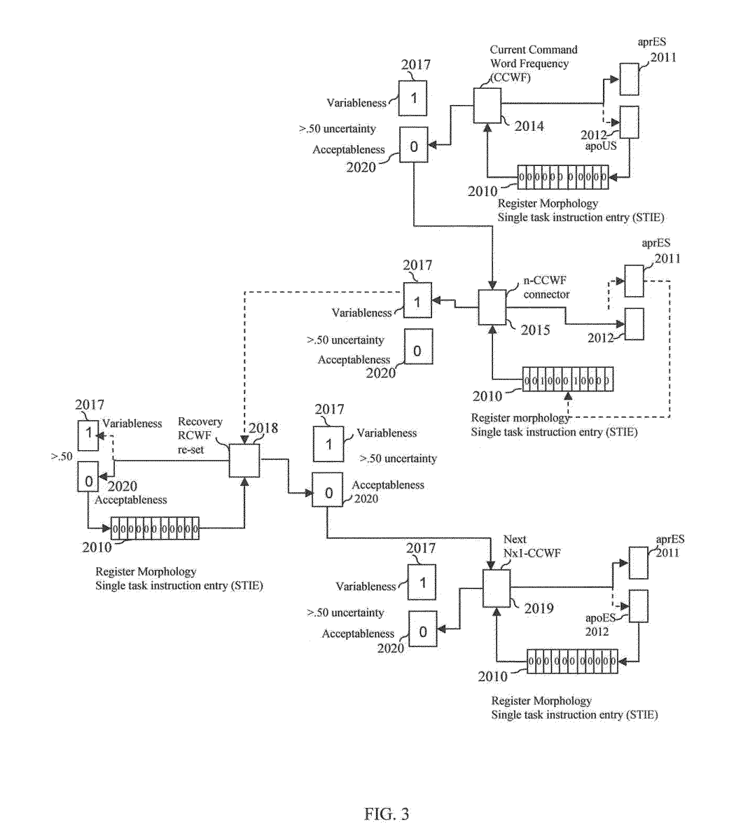

FIG. 1 is a schematic showing an overview of a dynamic system for transitioning an entity status prior or subsequent to a variableness as indicated by a heuristic, predicated on predicted neuronal assembly activation. To optimize the transitioning process of an entity state, electromagnetic interference may be received for a plurality of energy patterns (i.e. electron volt, volt, joule or terahertz) and/or frequency periods, as illustrated in FIG. 3A-FIG. 3E, and transitioned within the system.

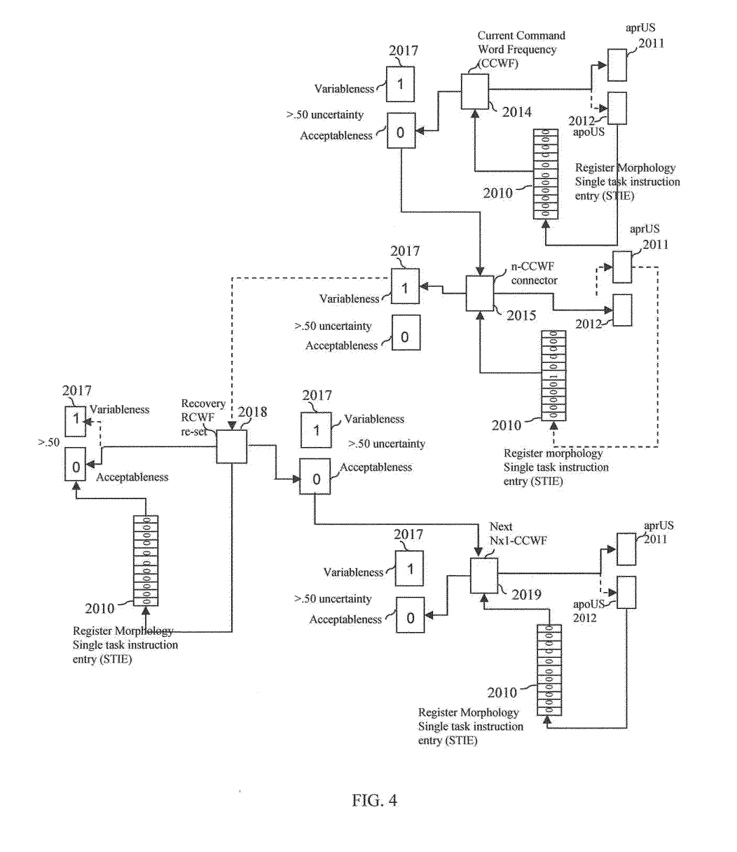

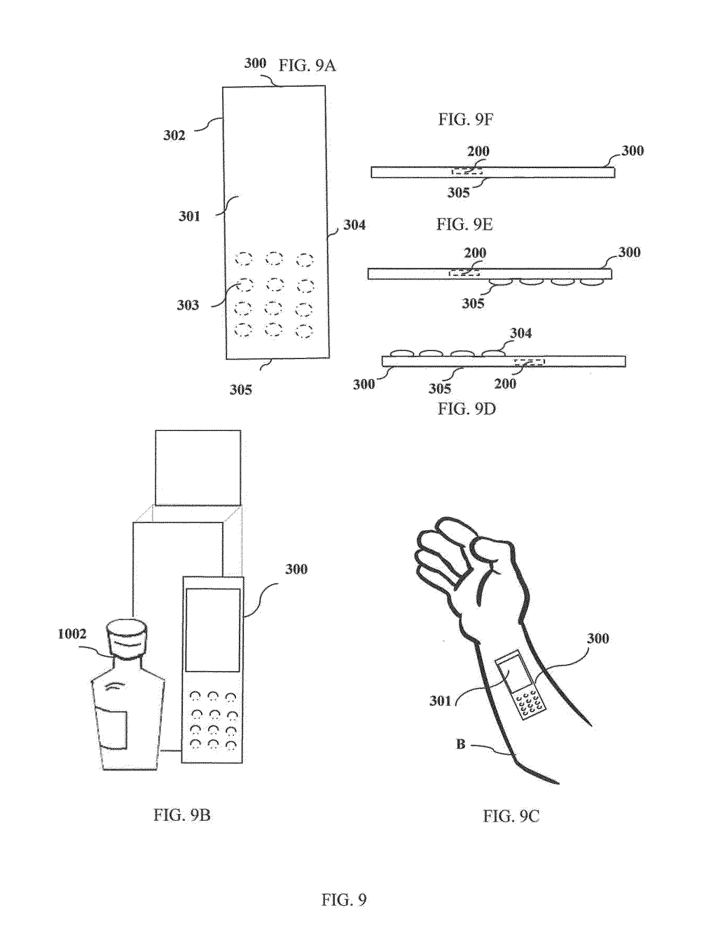

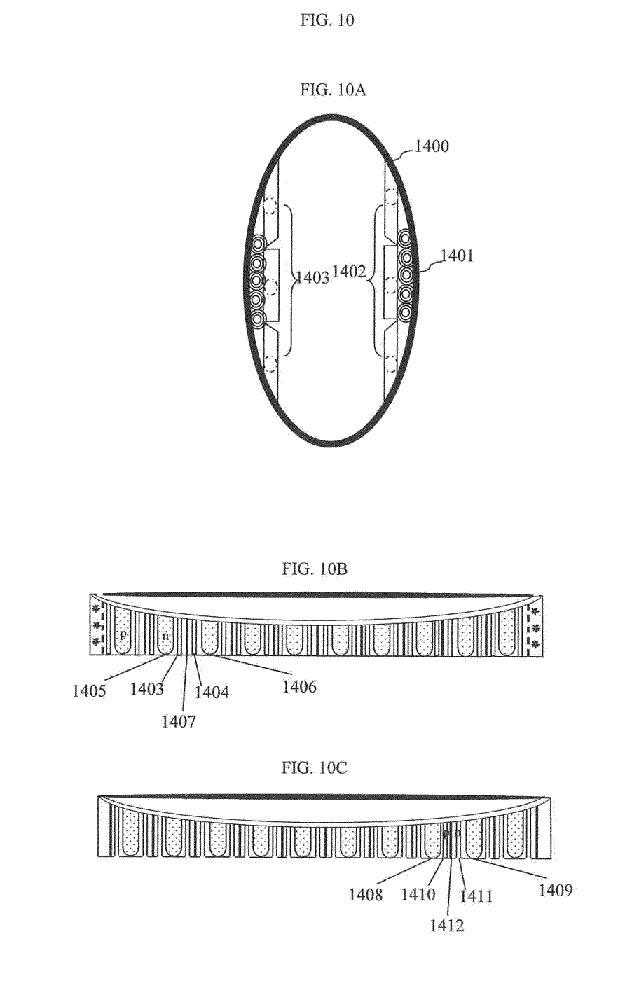

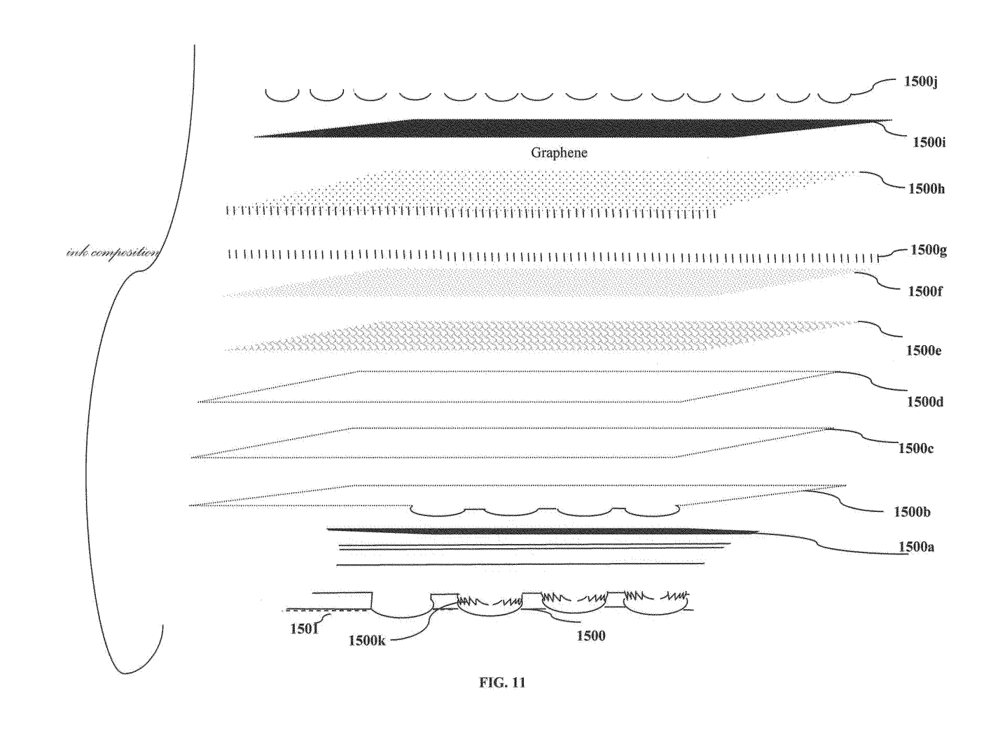

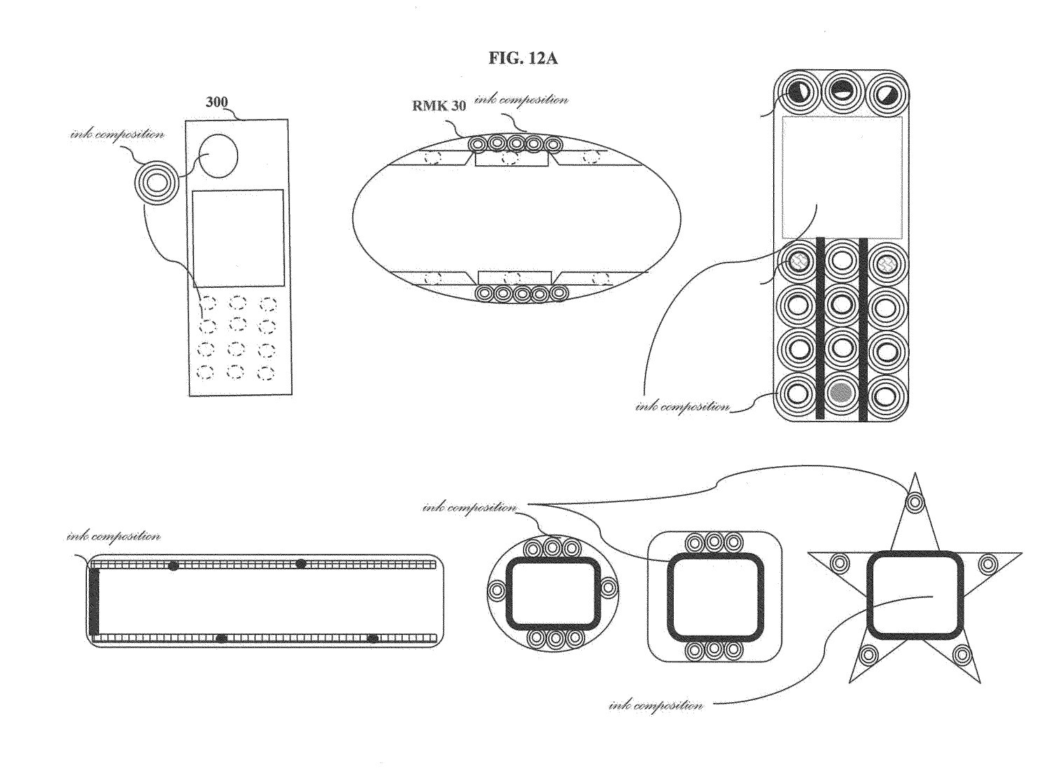

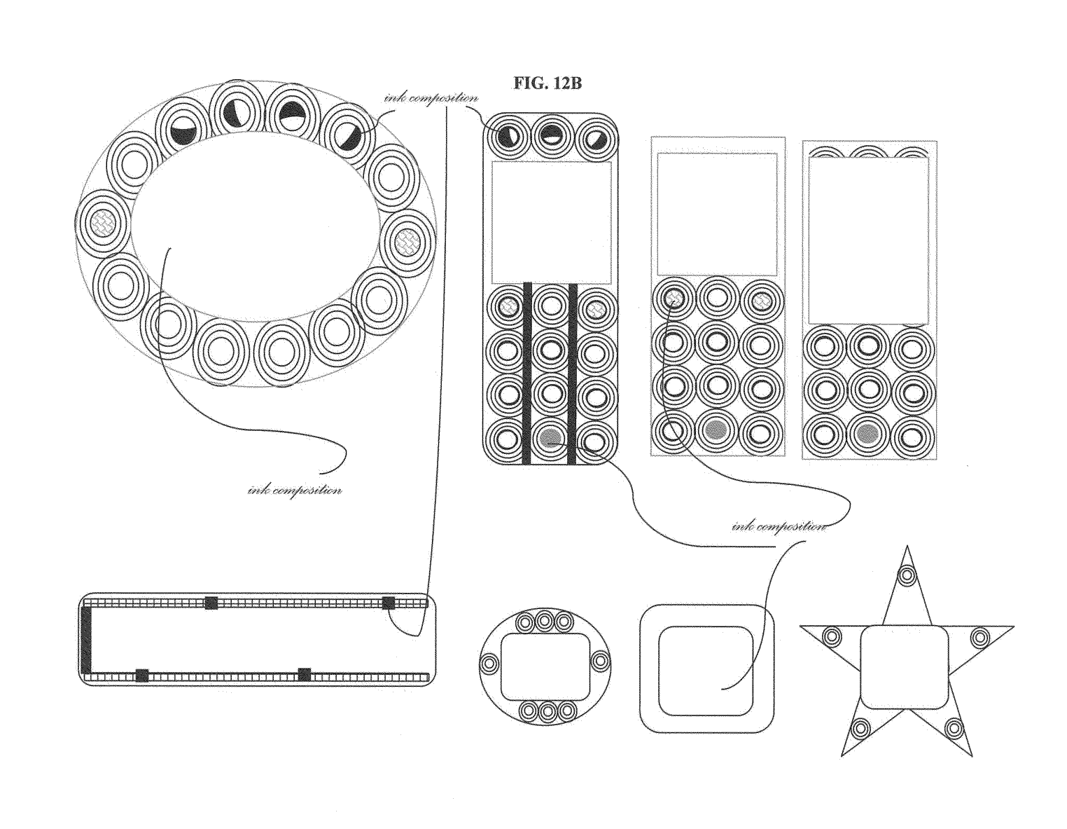

FIG. 2, is a block diagram of the primary components of a spontaneity-interference platform. The primary components of a spontaneity-interference platform for FIG. 2, FIG. 3, FIG. 4, FIG. 9, FIG. 10, FIG. 11, FIG. 12 may include, an entity status component 207, a frequency analyzer 215, an energy generator 208, a strategy component 210, a scenario generator 213, an interference component 209, a period optimizer 214, a buffer component 212, a challenge generator 211 (e.g. for use as a game), a microcontroller and a processing unit 201A or 201B or a plurality of processing units.

The entity status component 207 can include entity patterns for instruction, preferences, notifications, customizations, frequency transitions and intermediate intervention frequencies. Additionally, the entity status component 207 is configured to transition progress related information to the entity interface 205. The frequency analyzer 215 analyzes a frequency during an entity state transitioning and determines interference assigning input to the entity status configuration component 207 to transition the entity status as compared to a predicator using the strategy component 210. The frequency analyzer 215 may then identify or indicate the transitioning, using the entity status configuration component 207 based on a cognizance interaction using a plurality of frequencies (i.e. 506, 507, 508, 509) or energies generated by 208. Standard strategies common for an entity interaction at exemplary frequencies or generated energies, may have embedded heuristics at the frequency where a signal receiver 225 for receiving a signal may be configured within the communication interface 215, and may be further used to transition the interaction.

Received signals from a transitioning entity are communicated to the frequency analyzer 215 where an indicator of a transitioning entity status is transitioned to the interference component 209 for redirection. In one embodiment, the system architecture compares a set of indicators and identifiers of entity patterns at 215 for a frequency or electron volt at (i.e. 300-1100) with the heuristic predictor (i.e. each single task entry) conditioned by kinetic cognizance (i.e. memory, decision and response) interactions of the entity. The primary components of the spontaneity-interference platform for FIG. 2, FIG. 3, FIG. 4, FIG. 9, FIG. 10, FIG. 11, FIG. 12, may further include a display 216, a power supply 217, speakers in an audio configuration 202, a microphone 221 (where required by design), and where desired, camera components 220, depending on whether the primary components of the spontaneity-interference platform for FIG. 2, FIG. 3, FIG. 4, FIG. 9, FIG. 10, FIG. 11, FIG. 12, used as a processing platform (i.e. motherboard, discrete gate or transistor logic, a discrete semiconductor device, an application-specific integrated circuit or an independent entity interface.

Further, the primary components of the spontaneity-interference platform for FIG. 3, FIG. 10, FIG. 11 and FIG. 12, can include a processing unit 201A or 201B (or a plurality of processing units), a memory 219 (i.e. a self-assembled memristor), a bi-directional interface 205, an input configuration 203 and output configuration 204, an entity interface configuration 205, a communication configuration 215, a bus configuration 218, an audio/graphics vector component 202 and a power supply 217.

The processing units 201A and 201B can include a field programmable gate array (FPGA), general purpose processor, a microprocessor, one or more processing units or an embedded microcontroller (A), where such processing units as 201B typically perform with one or more of the above listed processing units. Communication interface 215 can be configured to communicate externally in any desired manner, preferably the primary components of the spontaneity-interference platform FIG. 2, FIG. 3, FIG. 4, FIG. 9, FIG. 10, FIG. 11, FIG. 12, operates in a combination environment for receiving “push to talk”, cognitive radio and biometric bidirectional, and terahertz communication. The primary components of the spontaneity-interference platform for FIG. 2, FIG. 3, FIG. 4, FIG. 9, FIG. 10, FIG. 11, FIG. 12, can further be integrated with a perforation or incorporated (i.e. by self-assembling and consequential self-organizing using the ink composition) for a sensor or a group of sensors (S) which can include, digital, laser, radio microwave, infrared, RFID, PIR, accelerometer, piezoelectric, temperature, ultrasonic or any and all such electronic fabrications, devices or combinations, which aid a learner/user/player and in some events a machine, detect or be notified regarding a variableness.

Cognitive constructs adapted for a heuristic, predicated on a predicted neuronal assembly activation, may also receive synchronous signal input from the entity interaction interface 205, communication configuration 215, audio component 202, display 216, sensor(s) (S), or from the communication shell for FIG. 2, FIG. 3, FIG. 4, FIG. 9, FIG. 10, FIG. 11, FIG. 12.

In one embodiment, the primary components of the spontaneity-interference platform for FIG. 2, FIG. 3, FIG. 4, FIG. 9, FIG. 10, FIG. 11, FIG. 12, may further be used for recognizing the real-time transitioning status of a entity or entities and in some instances of a machine, to optimize sustaining a cycle period. The primary components of the spontaneity-interference platform for FIG. 2, FIG. 3, FIG. 4, FIG. 9, FIG. 10, FIG. 11, FIG. 12, may also be used in another embodiment to assess and/or compare a required or requested exemplary frequency or generated energy (i.e. electron volts, volt, joule or terahertz). Here, a frequency is representative of a kinetic cognizance state for the variableness at a frequency interval or user transitioning time at the frequency and the generated energy is the indicated energy (i.e. 300-1100), during a cycle period (i.e. 300) or during a plurality of cycle periods (i.e. 500-600).

Receiving asynchronous signals relative to low frequency neural functions may use a receiver, actuator and in some embodiments a modified superconducting quantum interference configuration within 1400 (SQUID), (i.e. radio frequency (RF) or direct current). In one embodiment, the primary components of the spontaneity-interference platform for FIG. 2, FIG. 3, FIG. 4, FIG. 9, FIG. 10, FIG. 11, FIG. 12, may operate like an RF SQUID by incorporating the functionality and construction of a single Josephson junction. Further, in another embodiment, the primary components of the spontaneity-interference platform for FIG. 2, FIG. 3, FIG. 4, FIG. 9, FIG. 10, FIG. 11, FIG. 12, may operate like an RFID connector assemblage integrating terahertz radiation. For example, where a cognitive construct correlates to a kinetic interaction (i.e. decision, memory, response), a heuristic neuronal synchrony for an exemplary list of learning cognitive constructs may include but is not limited to word commands predicating for organizing, exemplifying, inferring, explaining, summarizing, interpreting, classify, comparing, summarizing, differentiating, organizing, attributing, checking, critiquing, deciding, executing hypothesis generation, planning, implementing plan, executing task, understanding and recalling.

Further, a kinetic cognitive construct may be layered, by or within the primary components of the spontaneity-interference platform for c FIG. 2, FIG. 3, FIG. 4, FIG. 9, FIG. 10, FIG. 11, FIG. 12, correlated for generated energies (i.e. electron volts, volt, joule or terahertz) pattern relative to motivation, pleasure, perception, conflict, reward, anger, stress, frustration, and significantly uncertainty. The functionality of a code command using the frequency analyzer 215 and the generating energies (i.e. electron volts, volt, joule or terahertz pattern) 208, may couple to or correlate within a Josephson junction while the frequency metrics, via interaction and sensor (se) configurations, may be transferred through a SQUID interface. However, preferably, the primary components of the spontaneity-interference platform for FIG. 2, FIG. 3, FIG. 4, FIG. 9, FIG. 11, FIG. 12 utilize a connector assemblage RFID, integrating oscillating band or ribbon configurations of 1401, 1411 and 1412 of FIG. 10C, to more simply generate, process and transition generated terahertz lattice vibrations to generate, process, transfer and absorb light indicators and identifiers for managing spontaneity-interference using the varying widths of frequency-tunable terahertz waves.

Exemplary frequencies (i.e. 300-1114 within a single instruction task cycle period) and time during a frequency, are important indicators and identifiers throughout the transitioning of an entity status for either a live entity or a machine, involving learning during an instructional game means (i.e. modules 400-600 and/or module 1100), to operation execution during operation modules (i.e. 500B, 600B, 800, 900 and/or 1100). Thus, the frequency analyzer 215 facilitates and optimizes, via processing unit 201A, an entity transitioning using in one embodiment an extended morphological field analysis algorithm.

Further, a plurality of algorithms (i.e. simple addition, subtraction, multiplication and division to more complex principal component analysis, the Rasch model, cycle detection, successive approximation and quantum computing) may be integrated using an extended morphological field analysis algorithm consistent with vector and matrix functions, especially for electromagnetism interaction, depending upon the requested investigation or use. While a particular algorithm may better address the desired request, one skilled in the art will realize such algorithms do not change the focus of the current invention.

FIG. 3 and FIG. 4 are diagrams of processes performed by registers 2010 on information predicated by a word command at frequency. At P(200), an entity status (defined as an a priori aprES 2011, and a posteriori aprES 2012) interacts with a frequency 2013. For exemplary purposes, in one embodiment, the system solicits an entity interaction at a current command word frequency CCWF 2014, to the next word command at frequency NCCWF 2015. Subsequent to an entity interaction at a specific word command at frequency (e.g. n-CCWF 2014, NCWF 2015, RCWF 2016 and Nxl-CCWF 2018), the primary components of the spontaneity-interference platform for FIG. 3, FIG. 10, FIG. 11 and FIG. 12, to include hardware resister 2010, may access entity interaction as compared to the heuristic 2017 (i.e. variableness matched to a predicated frequency or plurality of frequencies). The state of frequency (e.g. correctness or variableness) at the time of the entity interaction and an entity status at NCWF 2015, is determined in this instance, as an a priori transitioning entity status and is transferred to recovery word command at frequency RCWF 2018. The results of the variance interaction may be recorded and subsequently presented to the entity in an interface 2015 or a display 2016 and/or transferred to a third party via 2015. Upon recovery to a transitioning an a posteriori entity status aprES 2012 (e.g. for this example), the user continues on to the next Nxl-CWF 2019.

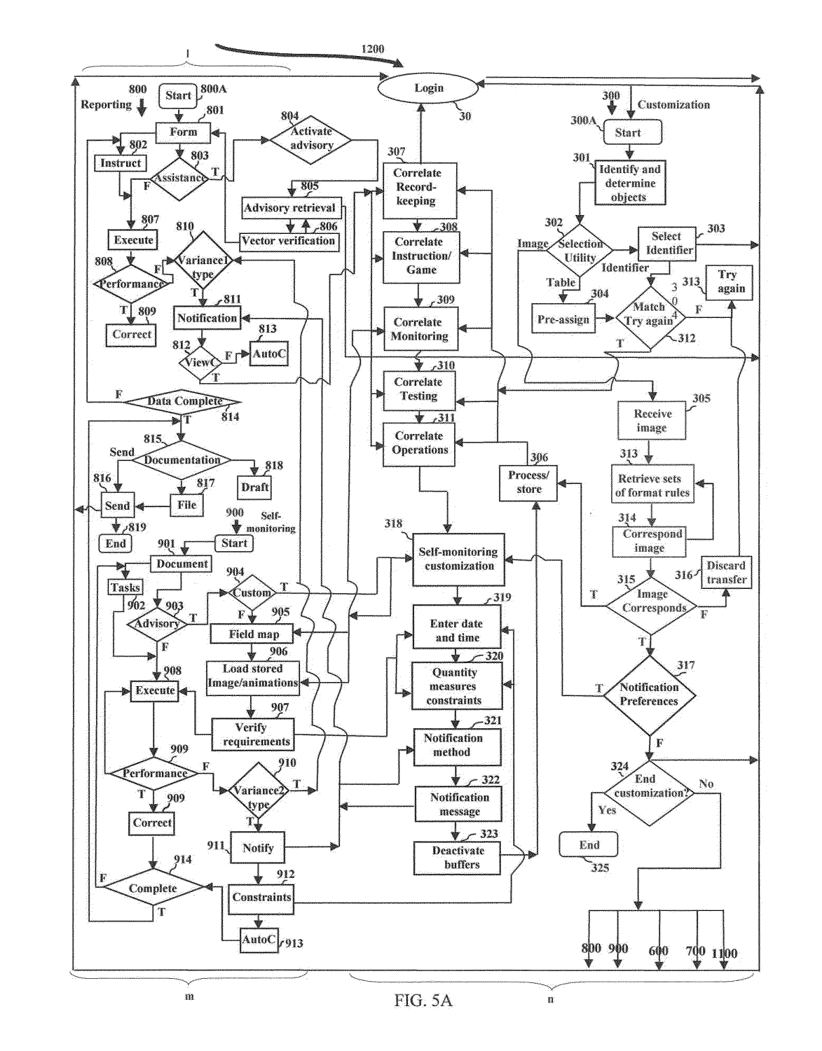

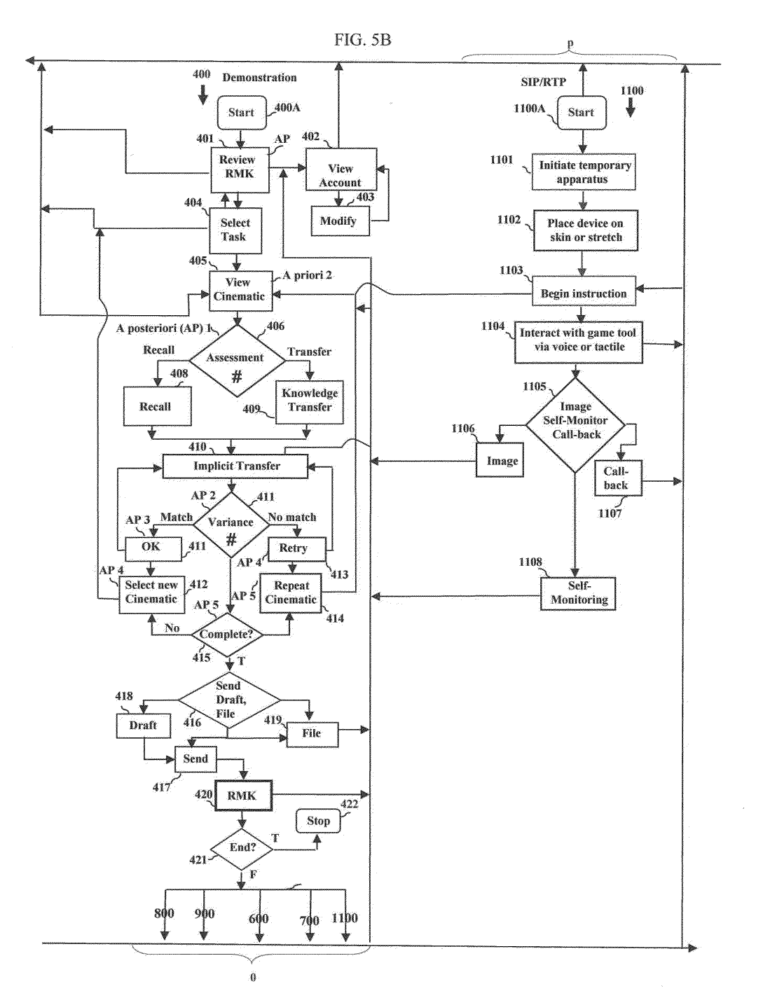

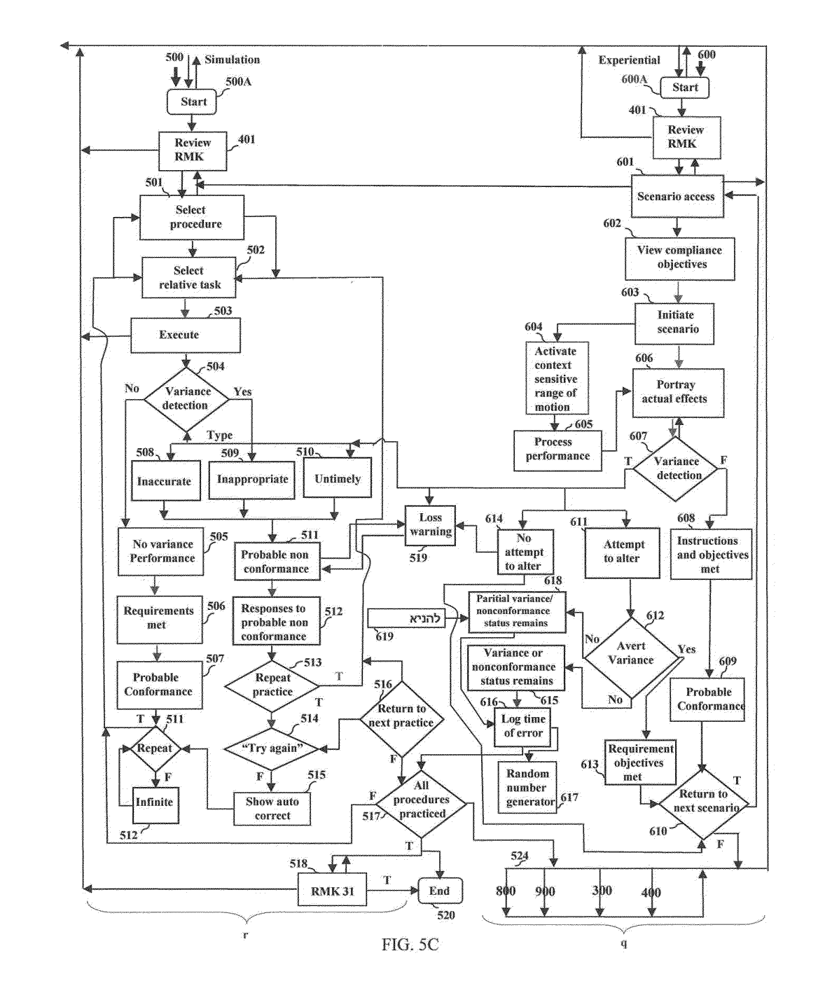

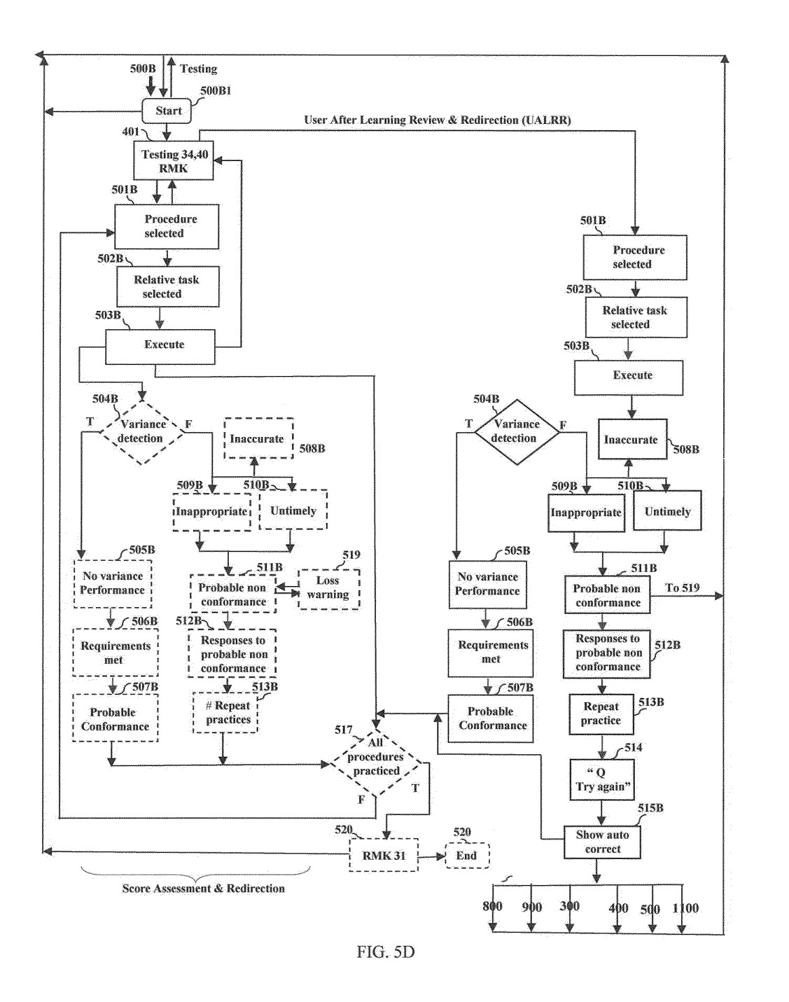

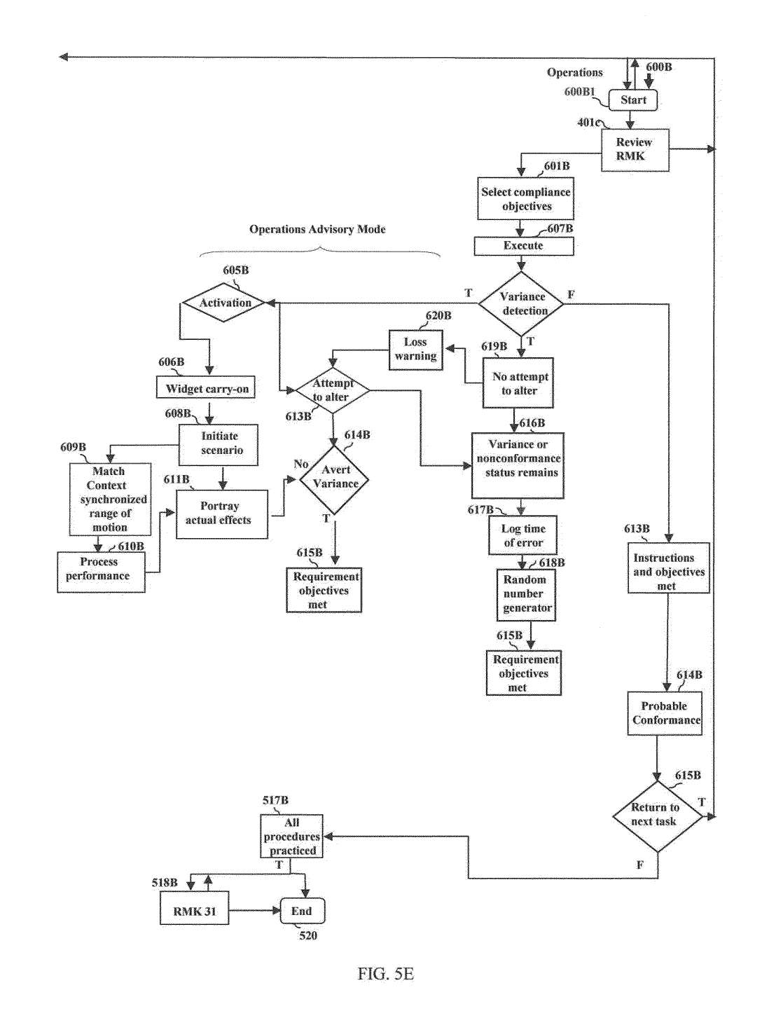

FIGS. 5A-FIG. 5E are flowchart diagrams of a transitioning entity status processing at frequency interconnections within an exemplary cycle 300-1114 of a current transfer system architecture. Subsequent to an entity interaction with the specific frequency, the entity status may transition depending upon the correctness or variableness of the interaction. Within the current embodiment, the desired transitioning status after an initial learning/knowledge acquisition, is an a posteriori entity status, however, entity status variableness, as a functionality of the current embodiment, may also indicate: (a) pre a priori, (b) pre a posteriori during a customization cycle 300-323, (c) a priori to (d) a posteriori and (e) a posteriori to a priori status during a demonstration cycle 400-423, during a practice cycle 500-523, and during an experiential cycle 600-623. An entity status variableness may further transition form a state (f) a posteriori to a priori to a posteriori user status during a testing cycle 500B-523B, an operations cycle 600-623 during a recordkeeping cycle 800 and/or during a self-monitoring cycle 900.

Transitioning an Entity Status for Instruction Acceptableness During a Cycle Period

In some embodiments, an entity can access the system architecture through a security level at 1200 that can be encrypted. The encryption process is based on a factored process of the core using an extended morphological field analysis algorithm depending upon the constraint type by which the entity is to configure the primary components of the spontaneity-interference platform for FIG. 3, FIG. 10, FIG. 11 and FIG. 12.

FIG. 5A reflects and the frequency schematic of module 300 when customization is organized to established memory triggers or cues for conditioning a transitioning an entity. Here indicators and/or identifiers are collected for base-lining cognizance. Based on the cognitive construct strategies for each single task entry, indicators are categorized as either a pre-a-priori or a pre-a-posteriori user status. Also integrated with each schematic of module 300 is a mapping function correlating an entity frequency including generated electron volts, within the system architecture. Also illustrated in FIG. 5A, is an exemplary correlation depicting customization interactions with reporting and self-monitoring frequency schematics in modules 800 and 900 respectively.

FIG. 5B reflects a schematic to baseline terahertz frequency or electron volt generation at a first or new intrinsic knowledge demonstration at module 400. Here, the entity configuration component 207 of an entity frequency is established for indicating and/or identifying a transitioning entity from a status of a pre a priori to a status of a pre a posteriori. Also integrated within each schematic within configuration 400 is a mapping function correlating the frequency configurations at component 207 to components of the system architecture. Further illustrated in FIG. 5B is an exemplary frequency schematic between the demonstration mapping functions that may be configured by primary components of the spontaneity-interference platform for FIG. 3, FIG. 10, FIG. 11 and FIG. 12.

FIG. 5C is a schematic diagram for comparing the terahertz frequency and electron volt configuration within the system architecture for indicating and/or identifying transitioning a priori to a posteriori entity status during a practice in configuration 500. Also integrated with each schematic of configuration 500 is a mapping function correlating the entity frequency and generated terahertz within the system architecture (i.e. illustrated in FIG. 5C, is the exemplary correlation a frequency schematic during interaction between experiential within configuration 600.

FIG. 5D is a schematic for terahertz frequency and generated electron volts within the system architecture for indicating and/or identifying transitioning a posteriori to a priori to a posteriori user status during in an exemplary testing 500B schematic. Also integrated with each schematic within configuration 500B is a mapping function correlating the user frequency and generated electron volts within the system architecture (i.e. pictured in FIG. 5C, is the exemplary correlation a frequency schematic during interaction between the tested frequency schematic in 500B and the re-coding frequency schematic in 500C.

FIG. 5E reflects a schematic for terahertz frequency anthology within the system architecture for indicating and/or identifying transitioning a posteriori to a priori to a posteriori entity status during in an exemplary operations 600 configuration. Also integrated with each schematic of configuration 600 is a mapping function correlating the entity frequency and electron volts within the system architecture

Of note, the following detailed description of cognizance interrelationships for determining a transitioning entity status is described relative to each exemplary terahertz frequency and generated electron volts (e.g. 301 . . . 1014) in the period (300-1014). However, based on the adaptability of the core architecture, a cognitive construct interrelationship for determining a transitioning status at each frequency or generated electron volt in a period, may include more than one frequency or generated electron volt, as an independent period. Further, the instruction heuristic, can be used as a pattern detector and conditioner, using moral cognitive indicators and identifiers at a plurality of frequencies and generated electron volts, while the entity transitions within a period (e.g. 301-1104). Still further, a challenge of cognizance for the entity to enhance the spontaneity by a single task instruction can be facilitated to pre-screen, base line, condition, refresh, reset, test, recode, reactivate and or recondition a transitioning status during a cycle period.

Further, for exemplary purposes, an entity has been accepted within a system which can include but is not limited to, a password, a morphologically generated encryption and/or any and all other n-dimensional determined means reconfiguring an entity identify. The example provided is for a human entity and not an animal or a machine and thus the entity reference is as a user. However, one skilled in the art will realize the reference to user does not change the focus of the current invention for an entity in one example that is a user/player/learner.

Customization

FIG. 5A shows a schematic illustrating one embodiment of the period cycle during an entity transitioning process in the present invention. The user's primary cognitive construct for initiating customization at frequency 300A, predicated on heuristic A, is an indicator of motivation, triggered by novelty and a drive to proceed if the user interacts with frequency 300A. The system architecture determines a pre-a posteriori status and assigns a buffer (i.e. interference) component which can include a memory (m), decision (d) and response (r). In contrast, a pre-a priori status is assigned with a memory (m) (i.e. buffer component) if the user does not activate 300A.

At frequency 301, the system presents a prompt in accordance with a terahertz frequency at 301, predicated on heuristic B, as an indicator of a need or preference for a visual reminder. Interaction with the system architecture, received from a user, continues to indicate motivation and an ongoing process of using specific objects. A pre-a posteriori user status is assigned for a frequency at 301 with a (d) buffer component, while a pre-a priori user status (m) is sustained if the user doesn't respond or stops the customization process. A pre-a posteriori user status (d) may be transitioned to a pre a priori user status (m) if the user doesn't respond or stops the customization process.

Depending upon the indicated user cognizance for object representation selection at frequency 302, predicated on heuristic D, an indicator of continued motivation and or interest by the user may be retained. A pre-a posteriori user status (d) is sustained at frequency 302, relative to correctness or acceptableness, while a pre-a priori user status (m) is sustained if the user doesn't respond or stops the customization process.

A preference setting for an image is indicated at frequency at 303, predicated on heuristic D, when the choice is a 3-D graphic representation. The user interaction is an identifier of visual recognition and preference, and an indicator of a pre-posteriori (d) user status, if the selections by the user continue at a terahertz frequency at 302 for the next object selection.

A preference setting for text is indicated at frequency at 304, predicated on E, when the choice is text representation. The user interaction is an identifier of symbol preference, and an indicator of a pre-a posteriori (d) user status, if the selections by the user continue at frequency at 302 for the next object selection.

A preference setting for spacio-temporal familiarity is indicated at frequency at 305, predicated on heuristic F, when the choice is an identifier of a user specified object representation (i.e. photograph, drawing, sketch) and preference, and an indicator of a pre-posteriori (d) user status recognizing an object on site, if the selections by the user continue at frequency 302 for the next object selection.

A pre-a posteriori user status is sustained for user interaction at frequencies 303, 304 and/or 305, relative to the correctness or acceptableness of the object selection which may be correlated to a predetermined image with the buffer component pre-assigned as (d). In contrast, a pre-a priori (m) user status is sustained for those image selections that do not match a pre-assigned image and a trigger component is pre-assigned as a memory buffer components.

A consolidation of images of the object representations is presented to the user at a frequency at 306 prior to storing, for user confirmation of the selections presented at frequency at 307, 308, 309, 310, 311. A correlation of the respective user's site-specific object representation as presented in the a display or interface correlates to an Aerial or bird's eye view at frequency at 307 frontal and/or posterior view frequency 308, perspective or 3-D views at a frequency at 309, side views at frequency 310 and frequency 311 predicated on heuristics I.

At frequency 318, a solicitation in accordance with a sequence predicated on heuristic J, is an indicator of motivation (d) to accept instruction if the user continues with the notification preferences within the customization plurality of a frequencies. A pre-a posteriori user status is determined at frequency 318, relative to planning with a pre-assigned (d) buffer component. In contrast, at frequency 318, a user interaction, predicated on heuristic K is an indicator of no attachment to a cognizance awareness as the user does not indicate an action and if subsequent actions identify variableness. A pre-a priori user status is determined at frequency 318, relative to planning with a pre-assigned (d) buffer component.

Variableness assembly activation patterns for a user status at a plurality of frequencies 319, 320, 321 and 322 respectively, relative to memory, summarizing and conflict heuristics L. The heuristic L, may result with conflict processing as the user status transitions between memory (m) for information entry at frequencies 319, and 320 respectively. An elevated activation predicated on heuristic M, is an indicator, if the user status (d) recalls method and message preference at frequencies 321 and 322. Further, heuristic N, is matched if the user status (d) initiates listening to the assigned message at frequency 322. Activation of the heuristic P, at frequency 323, is relative to conflict with the decision (i.e. resulting in (in) of deactivating the notification preferences or loss of protection. In contrast, when the user status (d) is secure with the decisions at frequency 323 heuristic O, is indicated.

A pre-a posteriori (d or m) user status is determined at frequency 318, 319, 320, 321 and 322 respectively, relative the correctness or acceptableness of constraint input preference selections which may be correlated to a predetermined image or action. The component support at frequency 318-322 is pre-assigned as a decision. In contrast, a pre-a priori user status is determined for constraint input preference selections by the user, that do not match a pre-determination, thus the trigger a memory component activation.

Demonstration

Consistent with user status cognizance indication at frequency 300, and relative at frequencies at 400, 500, 600, 800, 900 and 1100, are predicated on heuristics Q, as the user initiates a first action. The activation may result as an indication of the cognizance user status CUS), for assigning value to the loss or gain presented to the user.

CUS interrelationships upon activation at frequencies 401, 402, 403 are indicators for memory relevant to checking, error detection and correction respectively. A sustained or elevated predicated heuristic S, is the indicator. In contrast, an a posteriori user status is determined for frequencies 401, 402 and 403, relative to the correctness in identifying and correcting erroneous information, with component support pre-assigned as a decision.

A transitioning a-priori-to-a-posteriori (d) user status is sustained relative to the selection of a task at frequency 404, if the selection correctness is consistent with the strategy object determination in customization, at frequency 312. Additionally, a predicated synchronized neuronal assembly activation may result if a pre-a posteriori user status was also determined at frequency 312. In contrast, an a priori user status is determined for any frequency that does not match a pre-assigned requirement, with component support determined as memory.

In addition to a sustained or further elevated CUS at frequency 405 during the presentation of a cinematic, (indicating the heurisitic processing is predicted relative to the user (d) summarizing image features during the viewing of the demonstration cinematic, a graphic representation of an object). Additionally, the motor assembly may be activated if a hand or gesture is required for adjusting the cinematic. A synchronization predicated on heuristic U, is predicted at the end of the cinematic presentation, if the subsequent user (d) action at frequency 408 and frequency 409 results in a correctness or an acceptableness.

The more rewinding, pausing and/or stopping of the cinematic is indicative of conflict predicated on heuristic V resulting in a (m) designation. Further, reduction levels predicated on heuristic W, as an indicator of conceptual difficulty and an a priori user (m)status determination. Fast forwarding of the cinematic is indicative of an a posteriori status (d) if the user response at frequencies 407 and 408 results in a correctness.

An activation of the predicated heuristic X at frequency 406, is an indicator if the user (m) status is uncertain of the newly presented information. Verification of a status of a transitioning user status may be collected or captured at frequencies 406, 407, 409, 410, 411,412, 413, 414 and 415 respectively.

Upon the timed completion of a demonstration cinematic, interaction at frequencies 405, predicated on heuristic Y, may identify a cognizance of a user (d) status, as a transitioning a posteriori status, with the consistent strategy recall at frequency 407, predicated on heuristic Z. A further indicator may also generate a representative signal identifying a cognizance of a user (d) status, as a transitioning a posteriori status with the consistent strategy applied at frequency 408. Still further heuristic AA, may result during applied assessment at frequency 409, relevant to the conflict during an a-posteriori-to-a-priori-to-a posteriori user status (m) transitioning as the user status applies learned knowledge and or information.

A CUS (m) at frequency 410, predicated on heuristic BB, may indicate a conflict when presented with a response or notification to a variableness result. Activation of a predicated heuritstic BB, at frequency 409, with the presentation of a score, money or resources loss, relative to the user's (m) perception of expected loss and actual loss. Whether the loss in score or money is greater or less than user's expectation, the user (m) status difference is indicative of a priori if the difference is significant and a posteriori (d) if the response is expected by the user.

Thus, transitioning a priori to a posteriori user status is determined at frequencies 407, 408 409 and 410, show a consistency with correctness or acceptableness with component support pre-assigned as a decision. In contrast, an a priori user status is determined for any of the frequencies 407, 408 and 409 and 410 that do not match requirements, with component support pre-assigned as memory.

A predicated heuristic CC, at frequencies 412, 413 and/or 414, is an indicator of interest, motivation and a desire for more learning, if the user (d to m) sustains a transitioning a-priori-to-a-posteriori user status. Variableness assembly activation patterns for a CUS at frequency 411, relative to memory, summarizing and conflict heuristic DD, as the user status transitions between memory and information at frequency 411. Still further, the predicated heuristic CC, at frequency 411, is an indicator, if the user (in) status initiates listening and a more intense methodological (i.e. longer time, zoom, rotation) viewing of the display, as needed for evaluating a concept.

The CUS (m) at frequency 415, is an indicator of a lost interest and lost motivation and/or desire for exerting some type of control if the user initiates action at frequency 415 or ends at frequency 421. A transitioning a priori to a posteriori user status is determined for frequencies 415 or 421, relative to a correct response 411, with component support pre-assigned as a decision.

Practice

A user status cognitive construct at frequencies 401B-403B, predicated on heuristic DD, is a response to the loss or gain as reviewed by the user (m or d). An expected increase in review speed of frequency at 401B-403B, is indicative of a further user (d) status transitioning consistent with the object determination in customization at a plurality of a frequencies 312, 401A-403A, 405, when the variances presented to the user, are believed correct or no loss is observed. Additionally, a less transitioning activity (associated with understanding and long term memory activation occurrences) as the user becomes more familiar with the instruction tasks. In contrast, heuristics EE, may result if a loss is reported to the user that is not consistent with the user cognitive construct perception of the loss resulting in a (m) or interruption (r) result. Still further, interrelationships previously noted may also result based on degrees of variableness.

In addition, a sustained or further elevated CUS (d), is indicative of an activated neuronal assembly during the selection of a procedure at frequency 501 and frequency 502, predicated on heuristics FF. A cognitive construct assembly and/or the activation of predicated heuristic GG, is indicative of a user (d) status if an image is confirmed to the user on a display, during the viewing of a graphic representation of an object. A further indication of motivation and interest for a CUS (d), is the consistent detection of correctness or acceptableness, predicated on heuristic HH, at frequency 502. A still further predicted activation, predicated by heuristics II, at frequency, indicates when motion to the graphic representation of an object is required by the CUS (d) to practice movement at frequency 503.

The predicated heuristic JJ at frequency 503, may be activated as indicated by a hand or gesture (d) as required for practicing human object interaction. The more range of motion interrelationships are indicative of assembly activation JJ, that may predict a cognizance (r). In contrast, a reduced generation of heuristics KK, is indicative of conceptual difficulty (m) in remembering object use and/or steps, indicating an increased generation of heuristics LL for planning, organizing, and an increased generation of heuristics MM (r), relative to conflict interrelationships. As all activations, are indicative of cognizance processing for the selected learning instruction task, a higher assessment is predicted for transitioning a posteriori user (d) status after the practice of a human object interaction at frequency 503.

Upon the timed completion of an executed practice cycle at frequency 503, a synchronized assembly activation may generate a representative signal identifying a CUS (d), as a transitioning a posteriori status of the object identity and procedural steps. Verification at frequency 504 of a transitioning a posteriori status is relevant to the consistent and sustained performance indicating no variableness of strategy at frequency 505, predicated on heuristic NN, by the user status (m). A predicated heuristic OO, at frequency 506, indicates acknowledgement and confirmation of reward relevant to a transitioning user (d) status. A further, synchronized assembly activation may also generate a representative signal identifying a CUS (d), as a transitioning a posteriori status with the consistent user verification of strategy correctness at frequencies 506 and 507 respectively.

In contrast, (e.g. temporal lobe activation exchange between the frontal lobe and predicated heuristics NN, at frequency 511, indicates a result during the user response to repeat the previous practice relevant to a internal conflict or variableness to duplicating correctness. A CUS at frequencies 505, 506, 507, predicated on heuristics OO, at frequency 505, is an indicator of a conflict when presented with a response. A further activation of predicated heuristic PP, at frequency 511, is an indicator if user status sustains an a posteriori user (d) status. Thus, an assembly activation at predicated heuristics QQ, at frequency 509, is an indicator when the CUS is determined as a transitioning a posteriori user (d) status.

A transitioning a posteriori user (d) status is determined at the frequencies 505, 506, 507 respectively, relative to constraint input preference selections at frequencies 303, 304, 305, 318, 319, 320, 321, 322, 323 and correctness or acceptableness, correlated with a predetermined image or action at frequencies 307, 308, 309, 310, and 311. The buffer component support for frequencies 505, 506, 507 511 and 512 is pre-assigned as a decision. In contrast, an a priori user status is determined for those constraint input preference selections, that do not match a pre-determined image, thus the component support at frequencies 508, 509 and 510 becomes a response. Deviations from the normative order an a priori path set at frequency 508, is an indicator if an awareness of steps need to be refined or order, indicating a predicated heuristic QQ, predicted on neuronal activation in the prefrontal cortex.

A variableness at frequency 509, of the addition or omission of steps in a procedure of a plurality of single instruction tasks, indicates an a priori status (m) as the user does not recall or understand the procedure or task relevant to a predicated heuristics RR. In contrast, a variableness at frequency 509 of the addition or omission of sequences in the procedure or task may indicate a transitioning a posteriori (c) user status if the inappropriateness improves elements in any part of a procedure of a plurality of and or a single instruction task, predicated by heuristic SS.

A variableness at frequency 510, is an indicator of a transitioning a posteriori status as the user indicates a cognizance for memory and a conceptual understanding of the assigned procedure or task relevant to a predicated heuristics TT, relevant to the speed of the execution by the user. Therefore, a transitioning a-priori-to-a-posteriori user (d to m) status is determined for frequencies 508, 509 and 510 relative to variableness with component support pre-assigned as response.

Variableness assembly activation patterns for a CUS predicated on heuristic UU, at frequency 504, indicates memory, summarizing and conflict with conflict processing as the user (m to r) status transitions between memory for information at frequencies 505, 506, 507, 508, 509, 510,511, 512 and the transitioning CUS at frequencies 513, 514 and 515. Further, predicated heuristics VV, at frequencies 505, 506, 507, 508, 509, 510,511, 512, if a continued range of motion practice is ongoing at frequency 503. Still further, an assembly and/or activation in the predicated heuristic at frequency, is an indicator if the user status relies on a listening pattern occurring in human object interactions indicating a more methodological evaluation of the practice session.

The predicated heuristics XX, at frequencies 514, 515 and 519, subsequent to the presentation of a correctness, are indicators of a conflict (r) relative to a user's perception of range of motion interactions to a strategy default. Further, predicted heuristics YY, at frequency 519, is an indicator, if during the presentation or notification of a score, money or resources loss may results with a conflict relative to the user's (m) perception of expected loss and actual loss. Whether the difference in perception is greater or less than expected the user status difference is a further indicator of a transitioning user (m to r) status. A transitioning a-priori-to-a-posteriori user (m to d) status is determined at frequencies 514, 515, and 519, relative to correct or acceptable interaction with a buffer component support pre-assigned as a decision. In contrast, a transitioning a priori user (d to m) status is determined at frequencies 514, 515, and 519, relative to variableness with component support pre-assigned as a response. Further, predicated heuristics ZZ, at frequency 520, may occur after a sequence of variableness are presented to the user.

Experiential

An automatic visual attention to an expected increase in review speed at frequencies 401D-403D, is indicative of a further user status transitioning consistent with the object determination in customization at frequencies 312, 401A-403A, 405i . . . j, 401B-403B, 501i . . . j, relevant to correctness or acceptableness. Additionally, a synchronized assembly activation is predicted with a more permanent level of transitioning associated with understanding and long term memory activation).

In contrast, predicated heuristics AAA, may result if a loss is reported, that is not consistent with a CUS (r) perception of the loss. Still further interrelationships, may also result in variableness degrees. In addition, a sustained or further elevated CUS activation during the selection of procedure at frequency 501, predicated on heuristic BBB. Frequency 502, is indicative of pleasure when viewing a graphic representation of an object on a display if the subsequent actions result in correctness (d) or no variableness (m to r). A still further activation is the predicated heuristic CCC, at frequency 503, is an indicator, when motion between the graphic representation of an object requires a CUS to practice/reaction/response movement.

The activation of a motor assembly when a hand or gesture is required for an interaction at frequency 603. The more range of motion interrelationships and speed of response to such, is an indication of cognizance (d) exchange predicated by heuristic DDD. Further, predicated heuristic EEE, at frequency 604 is an indicator memory for recalling previously learned activity. Strategy processing predicated on heuristic FFF, at frequency 606, is an indicator of validating previously learned activity (r).

Further, predicated heuristic GGG, at frequency 605, is an indicator of a more methodological processing of the practice if a user relies on a listening pattern occurring in human object interactions. Still further, predicated heuristics HHH, at frequency 606, is an indicator of conflict (r) during an a-posteriori-to-a-priori-to-a posteriori iteration, if a user status applies a learned knowledge. As all user activations, are indicative of cognitive construct processing for the selected learning/instruction and/or information delivery task, a higher assessment is indicated for transitioning a posteriori user status after that practice of a human object interaction scenario at frequency 607.

Upon the timed completion of a practice, a synchronized assembly activation may generate a representative signal identifying a cognitive construct of a user status, as an a posteriori transitioning user status with the correctness at frequencies 602, 603, 604, 605 and 606 with the component pre-assigned as decision. In contrast, an a priori transitioning user status is determined at frequencies 602, 603, 604, 605 and 606 relative to variableness with component support pre-assigned as a response.

An identifier, validating an a posteriori user status transitioning at frequency 608 with the consistent and sustained performance to a scenario, at frequency 603, predicated on heuristics III, where frequency 608 is an indicator of acknowledgement and confirmation of reward relevant to a transitioning user status. A further, synchronized assembly and/or activation is predicted to generate a representative signal identifying a cognitive construct of a user (d) status, as a transitioning a posteriori status with the consistent strategy applied at frequency 609, relevant to probable compliance (d) and the notification of a requirement being met at frequency 613. A cognitive construct of a user status, is pre-determined a posteriori transitioning user status with the correctness at frequencies 608, 609, and 613 with the component pre-assigned as decision.

In contrast, an a priori transitioning user status is determined for frequencies 608, 609, and 613, relative to variableness with component support pre-assigned as a response. Further, predicated heuristic JD at frequency (e.g. a predicted neuronal assembly activation of a transitioning a priori user status if a user execution of an instruction is excessively complex relative to timed response and the achievement of the assigned objectives.

Still further, predicated heuristics KKK, at frequency 611, is an indicator of an advance in practice if the proceeding practices of a sequence of variance, relative to a transitioning a posteriori (d to m) user, alerts the system of user relevant to the potential for a variant or variableness in performance resulting in a response assignment.

A predicated heuristic LLL, at frequency 611, is an indicator of an a priori transitioning user status if an attempt to alter error at frequency 615 is in conflict if a notice of loss at frequency 519 is significantly different than the user's (r) perception of the difference.

A predicated heuristic MMM, at frequency 614, is an indicator of a conflict for the user when the user responds at frequency 607, if the response results in the user not addressing the variance at frequency 615. Frequency 615, further indicates a user status variableness if a correctness is not achieved at frequency 617 in which frequencies 614, 615, 616, and 617 result in response buffer component assignment.

Implications for not attempting to correct an error indicated from a predicated heuristic NNN [000], at frequency 611, is an indicator of an emotional trigger that reduces an activation, exchange or assembly. At predicated heuristic OOO, at frequency 612, a user (m to d) action indicates activation of recall (e.g. correctness and of self-awareness of how the consequence impacts the user). In contrast, implications for not attempting to alter variableness, may indicate a cognitive construct of moral cognition requiring a special response (mor) component.

If the variableness is averted at frequency 612, heuristic OOO, relative to value and reward with requirements met at frequency 613 and no remaining variableness at frequency 615, indicates an a posteriori transitioning user status with a component pre-determined as decision, further implying an understanding of the correctness. Further, predicated heuristics OOO, at frequency 612, is an indicator relevant to transitioning a priori user status finding the execution of the instruction excessively complex relative to timed response and the achievement of the assigned objectives. Still further, predicated heuristics, at frequency 618, where only a partial nonconformance status remains, is an indicator of uncertainty being both an a posteriori transitioning user status with a component pre-determined as decision where the requirement objections are met, implying an understanding of the correctness but also an indicator relevant to transitioning a priori user status where all the procedures were not practiced at frequency 517.

A log time of error for the frequency 618 is recorded and in one embodiment of the present invention computed as

$${r}_{n , n + 1} = \frac{{k}_{n} - {k}_{n + 1}}{{k}_{n} + {k}_{n + 1}} exp ( - 2 {k}_{n} {k}_{n + 1} {σ}_{n , n + 1}^{2} ) ,$$

where the computation is for the fresnel reflection coefficient between layer n n+1. A heavy side function H is then computed whose value is 0 for the negative argument (nonconformance) and 1 for the positive argument (requirement objectives met). As used in the present invention the function is for control theory and signal processing to represent a signal that switches on at a specified time and stays switched on indefinitely. The function is further used together with the Dirac delta function H=δ defined as loads in the metamaterials computed as H used in integration, and the value function at a single point where H does not affect its integral. Further, it rarely matters what particular value is chosen of H(0).
S is the set N of positive integers and
μ is the counting measure on N.

As represented in FIG. 5C, the Avert frequency 619, is presented to the user/learner/player (hereafter referred to as entity) [symbol] (translated in Hebrew). In one embodiment of the invention, the Avert frequency 619 is presented to the entity in their native language. In another embodiment of the invention, the Avert frequency 619, is presented to the entity as symbology (i.e. where the use of symbols represents a cipher (with a known key by the user for causing a Eureka effect) for aiding the entity record (i.e. 800-819) or retune a cognizance challenge at frequency 611, where an attempt to alter is an indicator of an advance in practice if the proceeding practices of a sequence of variance, relative to a transitioning a posteriori (d to m) user, alerts the system of user relevant to the potential for a variant or variableness in performance resulting in a response assignment protecting the nonconformance for meeting the requirement objectives.

The transitioning schematic for sustaining the execution of a single task instruction task (and/or a plurality thereof) can be modified. Depending on the aforementioned outcome to provide for the sustainability of an instruction execution during an cycle period, minimal or no interruptions allows the user to condition the transitioning user status database at frequencies 300-600 and utilize different component deterrents or augmentations as they become available and advantageous in advance or subsequent to a variableness in user status by preference.

Operations

At the successful completion of instruction frequencies, the modifications of each relative operation frequencies (500B-521C, 600B-623B, 800-914 and 1100-1114) at modules 800, 900, 500B and 600B and 1100, may be modified for managing user status transitioning due to the naturally occurring, sometimes unexpected and most often consequence of variableness. Thus, the heuristics assigned to customization and instruction frequencies (300-623) are reassigned respective to the cognizance outcome determined at each frequency for each single task instruction. The adaptable schematic frequency (300-623), and predicated heuristics, automatically assign to the operation schematics (500B-521C, 600B-623B, 800-914 and 1100-1114)

Heuristics Predicated on a Predicted Neuronal Activation and/or Assembly

A. Heuristic predicated on a predicted neuronal activation and/or assembly (e.g. hippocampus relative to memory encoding and consolidation, the striatum relative to novelty and/or the limbic system relative to motivation and reinforcing behaviors). B. Heuristic predicated on a predicted neuronal activation and/or assembly (i.e. the orbitofrontal cortex relative to autobiographic memories and medial temporal cortex relative to long term memory storage). C. Heuristic predicated on a predicted neuronal activation and/or assembly (i.e. orbitofrontal cortex and medial temporal cortex and anterior cingulated cortex relative to a level of conflict as the user status decides an image preference). D. Heuristic predicated on a predicted neuronal activation and/or assembly (i.e. medial temporal cortex prefrontal cortex relative to decision, visual cortex relative to pattern recognition in particular V1, hippocampus and parietal cortex relative to spatial memory, thalamus relative to the focusing of attention on most relevant feature, orbitofrontal cortex relative to a reward for correctness and/or anterior cingulate cortex relative to a level of conflict). E. Heuristic predicated on a predicted neuronal activation and/or assembly (i.e. pre-frontal cortex, orbitofrontal cortex, medial temporal cortex and/or frontopolar for a subconscious decision). F. Heuristic predicated on a predicted neuronal activation and/or assembly (i.e. pre-frontal cortex, orbitofrontal cortex, medial temporal cortex and/or frontopolar for a subconscious decision). G. Heuristic predicated on a predicted neuronal activation and/or assembly (i.e. posteriori medial frontal cortex). I. Heuristic predicated on a predicted neuronal activation and/or assembly (e.g. relative to the image dimension in hippocampus, parietal cortex, prefrontal cortex, orbitofrontal cortex, medial temporal cortex). Those images activating heuristic I in long term memory are predicted to produce gamma wave synchronously. J. Heuristic predicated on a predicted neuronal activation and/or assembly (i.e. hippocampus, prefrontal cortex and anterior cingulate cortex indicating a conflict if the user status is uncertain). K. Heuristic predicated on a predicted neuronal activation and/or assembly (i.e. medial temporal cortex, prefrontal cortex, hippocampus, striatum indicating novelty, motivation and/or desire for exerting some type of planning, organization or control). L. Heuristic predicated on a predicted neuronal activation and/or assembly (i.e. processing of motivation and memory in the medial temporal lobe relevant to planning and organizing, the prefrontal lobe cortex and conflict processing in the anterior cingulate cortex). M. Heuristic predicated on a predicted neuronal activation and/or assembly (i.e. anterior cingulate cortex). Heuristic predicated on a predicted neuronal activation and/or assembly (e.g. predicated on prediected medial temporal lobe). N. Heuristic predicated on a predicted neuronal activation and/or assembly (i.e. auditory lobe). O. Heuristic predicated on a predicted neuronal activation and/or assembly (i.e. anterior cingulate cortex) P. Heuristic predicated on a predicted neuronal activation and/or assembly (i.e. limbic cortex, relevant to reward or goal achievement and/or pleasure). Q. Heuristic predicated on a predicted neuronal activation and/or assembly (i.e. medial temporal cortex, prefrontal cortex, visual cortex and limbic cortex, indicating interest to continue, motivation and desire for further knowledge/information). R. Heuristic predicated on a predicted neuronal activation and/or assembly (i.e. medial temporal cortex, prefrontal cortex and visual cortex). S. Heuristic predicated on a predicted neuronal activation and/or assembly (i.e. medial temporal cortex, prefrontal cortex and visual cortex). T. Heuristic predicated on a predicted neuronal activation and/or assembly (i.e. hippocampus memory encoding and consolidation) and the striatum relative to novelty, the limbic system relative to motivation, the prefrontal cortex, orbitofrontal cortex, medial temporal cortex). U. Heuristic predicated on a predicted neuronal activation and/or assembly (i.e. producing gamma waves). V. Heuristic predicated on a predicted neuronal activation and/or assembly (i.e. anterior cingulate cortex). W. Heuristic predicated on a predicted neuronal activation and/or assembly (i.e. temporal activation). X. Heuristic predicated on a predicted neuronal activation and/or assembly (i.e. anterior cingulate cortex and limbic cortex relative to conflict and stress). Y. Heuristic predicated on a predicted neuronal activation and/or assembly (i.e. a synchronized neuronal assembly activation may generate a representative signal). Z. Heuristic predicated on a predicted neuronal activation and/or assembly (i.e. cascaded gamma signal by the user status with assembly and or activation is predicted in the temporal lobe and prefrontal lobe). AA. Heuristic predicated on a predicted neuronal activation and/or assembly (i.e. temporal lobe activation is predicted with an exchange between the frontal lobe activation). BB. Heuristic predicated on a predicted neuronal activation and/or assembly (i.e. predicted to result in the un-synchronizing of a neural assembly activation, relative to predicted activation in the anterior cingulate cortex). CC. Heuristic predicated on a predicted neuronal activation and/or assembly (i.e. the auditory lobe and visual cortex). DD. Heuristic predicated on a predicted neuronal activation and/or assembly (e.g. parietal lobe relevant to assigning value, as indicated by activation in the putamen). EE. Heuristic predicated on a predicted neuronal activation and/or assembly (i.e. anterior cingulate cortex activation). FF. Heuristic predicated on a predicted neuronal activation and/or assembly (i.e. indicating the processing of memory in the temporal lobe and prefrontal cortex). GG. Heuristic predicated on a predicted neuronal activation and/or assembly (i.e. pre-frontal cortex, visual cortex). HH. Heuristic predicated on a predicted neuronal activation and/or assembly (i.e. producing brain waves and activation of limbic cortex indicative of a calmness and/or pleasure when viewing a graphic representation of an object on a display). II. Heuristic predicated on a predicted neuronal activation and/or assembly (i.e. or synchronization of temporal lobe, frontal lobe motor cortex and visual cortex) JJ. Heuristic predicated on a predicted neuronal activation and/or assembly (i.e. temporal lobe, frontal lobe, parietal lobe and motor cortex). KK. Heuristic predicated on a predicted neuronal activation and/or assembly (i.e. temporal activation). LL. Heuristic predicated on a predicted neuronal activation and/or assembly (i.e. frontal lobe). MM. Heuristic predicated on a predicted neuronal activation and/or assembly (i.e. anterior cingulate cortex activation). NN. Heuristic predicated on a predicted neuronal activation and/or assembly (i.e. ACC activation). OO. Heuristic predicated on a predicted neuronal activation and/or assembly (i.e. an un-synchronizing of the assembly activation and an activation of the anterior cingulate cortex). PP. Heuristic predicated on a predicted neuronal activation and/or assembly (i.e. temporal lobe and frontal lobe indicating interest, motivation and a desire for more information). QQ. Heuristic predicated on a predicted neuronal activation and/or assembly (i.e. temporal, frontal and visual cortex) RR. Heuristic predicated on a predicted neuronal activation and/or assembly (i.e. activation of the orbitofrontal cortex). SS. Heuristic predicated on a predicted neuronal activation and/or assembly (i.e. the predicted neuronal activation of the orbitofrontal cortex, primarily associated with creativity and problem solving). TT. Heuristic predicated on a predicted neuronal activation and/or assembly (i.e. a predicted activation of the orbitofrontal cortex and medial temporal cortex but a motor cortex disjunction). UU. Heuristic predicated on a predicted neuronal activation and/or assembly (i.e. frontal cortex and anterior cingulate cortex, indicating assembly activation in the anterior cingulate cortex). VV. Heuristic predicated on a predicted neuronal activation and/or assembly (i.e. activation of the motor area). WW. Heuristic predicated on a predicted neuronal activation and/or assembly (i.e. auditory lobe and visual cortex). XX. Heuristic predicated on a predicted neuronal activation and/or assembly (i.e. anterior cingulate cortex). YY. Heuristic predicated on a predicted neuronal activation and/or assembly (i.e. anterior cingulate cortex). ZZ. Heuristic predicated on a predicted neuronal activation and/or assembly (i.e. a predicted neuronal assembly activation predicated on the dorsal motor cortex, right inferior frontal junction, anterior insula and the rostral cingulated zone). AAA. Heuristic predicated on a predicted neuronal activation and/or assembly e.g. anterior cingulate cortex activation). BBB. Heuristic predicated on a predicted neuronal activation and/or assembly (i.e. predicted neuronal activation in the temporal (pleasure). CCC. Heuristic predicated on a predicted neuronal activation and/or assembly (i.e. synchronization of temporal lobe, frontal lobe, visual cortex assembly and motor cortex activation). DDD. Heuristic predicated on a predicted neuronal activation and/or assembly (i.e. temporal lobe, frontal lobe, parietal lobe and motor cortex at 604). EEE. Heuristic predicated on a predicted neuronal activation and/or assembly (i.e. reduced temporal activation is indicative of conceptual difficulty in remembering object use at sequences with increased prefrontal cortex and anterior cingulate cortex activation for planning, organizing and conflict interrelationships). FFF Heuristic predicated on a predicted neuronal activation and/or assembly (i.e. in the medial temporal cortex and motor cortex, is the predicted activation of range of motion or a reflex cognitive construct). GGG Heuristic predicated on a predicted neuronal activation and/or assembly (i.e. an neuronal assembly activation in the auditory lobe and visual cortex). HHH Heuristic predicated on a predicted neuronal activation and/or assembly (i.e. temporal lobe activation exchange between the frontal lobe activation). III. Heuristic predicated on a predicted neuronal activation and/or assembly (e.g. an assembly medial temporal cortex, prefrontal cortex, and/or predicted cascaded gamma signal. JJJ. Heuristic predicated on a predicted neuronal activation and/or assembly (i.e. a predicted neuronal assembly activation predicated on posterior medial frontal cortex, intraparietal sulcus, anterior insular cortices, premotor and lateral frontal cortex). KKK. Heuristic predicated on a predicted neuronal activation and/or assembly (i.e. a predicted neuronal assembly activation predicated on the dorsal motor cortex, right inferior frontal junction, anterior insula and the rostral cingulated zone). LLL. Heuristic predicated on a predicted neuronal activation and/or assembly (i.e. predicted neuronal activation of orbitofrontal). MMM. Heuristic predicated on a predicted neuronal activation and/or assembly (i.e. predicted activation of the anterior cingulate cortex). NNN Heuristic predicated on a predicted neuronal activation and/or assembly (i.e. predicted assembly activation predicated on the limbic cortex, and medial temporal cortex). OOO. Heuristic predicated on a predicted neuronal activation and/or assembly (i.e. orbitofrontal cortex). PPP. Heuristic predicated on a predicted neuronal activation and/or assembly (e.g. a predicted neuronal assembly activation predicated on posterior medial frontal cortex, intraparietal sulcus, anterior insular cortices, premotor and lateral frontal cortex occurs). QQQ. Heuristic predicated on a predicted neuronal activation and/or assembly (i.e. predicated on predicted neuronal assembly activation in the orbitofrontal cortex relative to autobiographic memories, limbic cortex relative to an elevation of stress and or parietal cortex relative to a recall effort). RRR Heuristic predicated on a predicted neuronal activation and/or assembly (i.e. a predicted neuronal assembly activation in the orbitofrontal cortex). SSS Heuristic predicated on a predicted neuronal activation and/or assembly (i.e. a predicted neuronal assembly activation in the orbitofrontal cortex). TTT. Heuristic predicated on a predicted neuronal activation and/or assembly (i.e. predicted on neuronal assembly activation in the orbitofrontal cortex relative to conflict). UUU. Heuristic predicated on a predicted neuronal activation and/or assembly (i.e. a predicted neuronal assembly activation predicated on posterior medial frontal cortex, intraparietal sulcus, anterior insular cortices, premotor and lateral frontal cortex). VVV. Heuristic predicated on a predicted neuronal activation and/or assembly (i.e. predicted on the neuronal assembly activation in the orbitofrontal cortex relative to future expectations).

### Cognizance Challenge

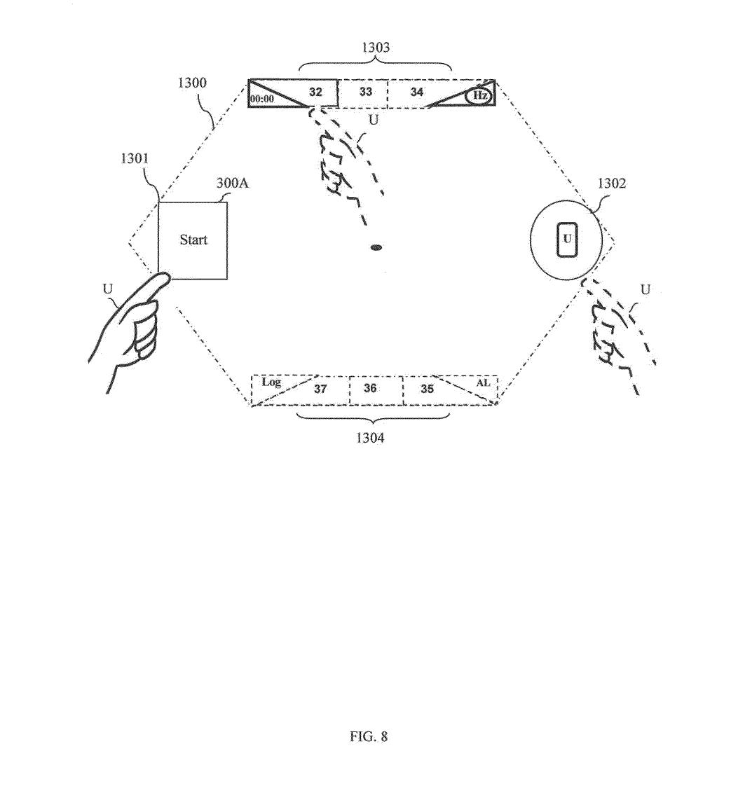

In an exemplary embodiment, the user is presented or accesses a cognizance challenge using 211 as illustrated in FIG. 8. Here, the heuristic frequency and or generated electron volts based for the cognizance challenge can be used for (1) base lining a priori knowledge, (2) re-setting an executed pace during a learning session, (3) re-coding an acceptable pace after a variableness when executing an instruction by incorporating frames per second, binaural beat and pitch, (4) improving the tempo, flow of an executed instruction to enhance motivation, (5) refreshing an entity's response time by providing impromptu interruptions and eliciting a Zeigarnik effect, (6) characterizing an entity's reset flow-time and non-acceptable responses to indicate and identify vulnerabilities that may require redirection (i.e. further action). The cognitive challenge may use in some embodiments gamma waves (i.e. 40 Hz and higher) for indicating higher mental activity, including perception, problem solving, fear, and a determined cognizance. Beta waves (i.e. 13-40 Hz) for indicating active, busy or anxious thinking and active concentration, arousal, cognition. Alpha waves (i.e. 7-13 Hz) for indicating relaxation (while awake), pre-sleep and pre-wake drowsiness. And in some embodiments, theta waves (i.e. 4-7) for indicating dreams, deep meditation, REM sleep and/or Delta waves (i.e. <4 Hz) for indicating deep dreamless sleep, loss of body awareness.

In one embodiment, the cognizance challenge integrates the standing wave ratio (SWR)

$$\vert Γ \vert = \frac{SWR - 1}{SWR + 1} .$$

SWR is used as an efficiency measure for transmission lines, electrical cables that conduct radio frequency signals (i.e. connecting radio transmitters and receivers with their antennas and distributing cable television signals). A reoccurring problem with transmission lines is that the impedance mismatches in the cable tend to reflect the radio waves back toward the source end of the cable which prevents the power from reaching the destination as well as no reflected power. An infinite SWT represents complete reflection, with all power reflected back down the cable.

In that reflections occur as the result of discontinuities (i.e. imperfections in the transmission line). For calculating the voltage SWR (VSWR):

$$VSWR = \frac{{V}_{max}}{{V}_{min}} = \frac{1 + ρ}{1 - ρ} .$$

and the SWR relative to electrical field strength where the voltage is a function of time t and distance x along the transmission line: V_{f}(x,t)=A sin(ωt−kx)

### Where:

V∫ is the forward wave amplitude,
A is the amplitude of the forward wave,
ω the angular frequency, and
k is the wave number equal to ω divided by the speed of the wave.
Or the voltage relative to the reflected voltage: Vᵣ(x,t)=ρA sin(ωt+kx).

In one embodiment a challenge for the entity is to execute an instruction(s) at a constant tempo, pace or flow and or combination thereof, and execute an instruction to match a predetermined acceptability based on a standard instruction. Here, the tempo, pace or flow and or combination thereof, of how the entity executes the instruction is indicative of an intrinsic level of knowledge or in other words an efficacy relative to an understanding of the method for accomplishing the task or procedure.

In a further exemplary embodiment, relative to the spontaneity/interference challenge, interne browser access (i.e. Microsoft Internet Explorer) is required to use this feature. The spontaneity/interference challenge includes: automatically presenting a word command frequency to cue a user interaction; clocking the pace of the user interaction; automatically presenting an image upon interaction by the user at the image frequency and storing the widget sequentially/non-sequentially interactions to satisfy the predetermined sequentially/non-sequentially interface challenge; repeating the spontaneity/interference for a next word frequency until the spontaneity-interference challenge is complete; prompting the user for a difficulty rating of the just sequentially/non-sequentially performed; and providing a flow, pace, tempo and or combination (FPST) score, based on the time, performance, mental effort and rating of the spontaneity-interference execution. In addition, the FPST score is determined as a result of a user interaction as compared with a predetermined pace, detecting any unacceptable interactions as compared to predetermined sequentially, by comparing time spent on the unacceptable interaction pattern for indicating a redirection.

Referring now to FIG. 8, is an illustration for integrating a challenge and rule structure of a system architecture within an interactive interface 1300 at 1300, assessing spontaneity. While knowledge domains are infinite, a technical advantage of the exemplary embodiment, is using an interactive interface with pre-determined response detectors 1301, 1302, 1303 and 1304, for indicating or identifying an acceptableness and recording the FPST and in some embodiments, cognitive construct characterization of the entity's interactions to assigned challenges.

In one embodiment, the placement of the response detectors may be used as a feature for challenging for cognitive constructs and heuristics for the processing of understanding, using right and left brain stimulators. Left brain stimulators are presented as text and right brain stimulators (however, the configuration can be change as required), are presented as a static or dynamic image while individual widgets within the tool bars may be presented as text, numbers, static of dynamic images and/or audio or other sensory interactions of which the user device is capable.

When the spontaneity game is presented to an entity, prior to an instruction session to establish a baseline for cognizance, the cognizance challenge begins with the word commands in the customization module to include interconnections (i.e. 301-325 in FIG. 5A). A cognizance challenge assessment using the word command schematic of 300-325, may be used for determining a familiarity with the object representations of required equipment and relative specifications (i.e. dates, times, quantity of measure and preferences for notification) of an single instruction task.

When a cognizance challenge is presented during an instruction execution, the spontaneity challenge begins with the word commands in the operation modules in FIG. 5A-FIG. 5B (i.e. interconnections during testing (501B-522B), operations (601B-623B), self-monitoring (901-914) or reporting (801-819). Spontaneity assessment using the word command schematic (e.g. 601B-1108) may be used for resetting an acceptable pace after a variableness.

When a cognizance challenge is presented to an entity, after an instruction session, the cognizance challenge can begin with any of the word commands in the schematic (i.e. 301-1108 within any of the configurations illustrated in FIG. 5A-FIG. 5B). Cognizance challenge assessment using the word commands in any schematic (i.e. 601B-1108) may be used for re-coding an acceptable pace after a variableness to refocus the entity upon encountering the variableness or an interruption, to assist the entity in re-instating an acceptableness (e.g. accuracy, appropriateness, flow).

When the cognizance challenge is implemented for improving the flow of an executed instruction to enhance motivation, the cognizance challenge may use any or all of the word commands (301-1108) of the schematic of the modules (for Instruction, Testing, Monitoring and Operations illustrated in FIG. 5A-FIG. 5B, and can be presented any time (i.e. before, during or after) relative to an instruction execution.

When the cognizance challenge is implemented for refreshing an entity's response time by providing impromptu interruptions and eliciting a Zeigarnik effect, the spontaneity game may use any or all of the word commands (301-1108) of the schematic of the modules (for Instruction, Testing, Monitoring and Operations illustrated in FIG. 5A-FIG. 5B, and can be presented any time (i.e. before, during or after) relative to an instruction execution.

When the cognizance challenge is implemented for characterizing an entity's reset flow-time and non-acceptable responses to indicate and identify vulnerabilities that may require redirection (e.g. re-setting, re-coding, refreshing), the spontaneity game may use any or all of the word commands (301-1108) of the schematic of the modules (for Instruction, Testing, Monitoring and Operations illustrated in FIG. 5A-FIG. 5B, and can be presented any time (i.e. before, during or after) relative to an instruction execution.

When the cognizance challenge is presented during an instruction execution improving the flow of an executed instruction to enhance motivation, the cognizance challenge can be implemented using any or all or the word commands in the schematic (i.e. 301-1108 in FIG. 5A-FIG. 5B.)

When a cognizance challenge is presented during an instruction execution refreshing an entity's response time by providing impromptu interruptions and eliciting a Zeigarnik effect of the micro-level method previously described, the spontaneity game can be implemented using any or all or the word commands in the schematic (i.e. 301-1108 in FIG. 5A-FIG. 5B.)

Security Game Using a Challenge-Response to Clear a Breech

In one invention of the present invention, an instructional game is provided for training a user integrating an RFID ID card and an RFID reader using terahertz radiation after a security breech. The goal of the game is to provide a hacking means for attacking a public RFID ID card; using an RFID reader to record just two timed attack challenge-response interactions with the RFID ID card; using a code book to compare the key; and reading all the data on the RFID ID card in the clear.

To begin the security game, a hacking means is provided where the public key parameters shared between the administrator and the RFIID ID card holder is breeched. In one embodiment of the game, the cipher text (where a pattern of plain text has been encoded in to unreadable language using letters symbols and numbers) has been converted to all readable plaintext using by mutating cryptographic primitives using malware. Further is the step of decrypting the public key on the RFID ID card using an integer factorization algorithm to mutate an encrypted public key in which the sender and receiver's key are different but computably related relative to a biometric authorization and an encrypted plaintext message pattern prepared in advance of a timed attack challenge-response interaction with the RFID ID card. In one embodiment, the hacking means uses the following integer factoring algorithm to access both the cipher texts and the code texts defined:

Lₙ[1/2,1+o(1)|=e^{(1+o(1))(log n)}^{^{1/2}}^{(log log n)}^{^{1/2}}.

In another embodiment, the security training game utilizes an RFID ID biometric authorization timed attack challenge-response interaction with an RFID ID card where the leaner interacts with the RFID ID card in which surface actuations comprising electroactive polymers, a piezoelectric and electrostatics, are conformational to the metal oxide adhesion of the RFID ID card detected by the RFID reader using terahertz radiation. Biometric authentication refers to the identification of humans by their characteristics or traits. Interactions, can include voice, DNA, hand print or behavior using metamaterials (i.e. the electrochemical and/or miscible composition of the present invention for devices such as directed light sources, lenses, switches, modulators and sensors compact cavities, adaptive optics and lenses, tunable mirrors, isolators, and converters, using the appropriate THz frequencies. More specifically, artificial magnetic (paramagnetic) structures, or hybrid structures that combine natural and artificial magnetic materials. Token based identification systems include driver's license or passports.

In another embodiment of the security game, a trainee accesses a code book stored in a network storage area and uses the code book for transferring large files (i.e. voice, DNA sequences) for deciphering the metal oxide adhesions relative to a sequence of biometric authentication correlated to a plaintext message pattern that has been encoded. Here, the trainee has previously used the cognitive challenge to enter patterns of responses where in one embodiment his fingerprints and the plaintext code were captured while the user entered a message challenge using the cognizance challenge interface then recorded and stored to establish the code.

In another embodiment of the instructional security game the administrator who accesses both the hacked key and the secure key reconciles both the two public keys and the challenge response. Further the newly read data now responds to a plurality of frequencies above the microwave range resulting from the magnetic coupling and inductive response to the metamaterials of the RFID ID card interacted upon by the holder and the RFID reader.

### System Architecture

Provided herein is a current system architecture supporting methods, systems, devices and computer readable medium for sustaining the acceptable execution of a single instruction task entry. FIG. 1 is an illustration of operating environment in conjunction with which devices, 200, 300, methods and computer-readable mediums 104 a-f, using the current system architecture may operate. The system preferably includes various configurations which may be implemented by means of software, for such transfer-to-practice devices using microcode, or within a network or portal, firmware, middleware for 104 a-f via bi-directional communication paths to wireless devices that can include, computers 102 personal digital assistant (PDA) 103, cellular telephone 104 and/or game console 105.

Further transfer-to-practice components can be accessible to hardware, such as computers 106 and 107 by reconfigurable tools 200A and 200B. As used herein, the hardware system of these embodiments can include a field programmable gate array (FPGA), discrete gate or transistor logic, a discrete semiconductor device, an application-specific integrated circuit, a digital signal processor (DSP), other discrete hardware components, or any combination thereof, and/or a processing platform 200.

A software system can include can include one or more objects, agents, lines of code, threads, subroutines, a module, a software package, a class, or a combination of instructions, data structures, or program statements, databases, application programming interfaces, web browser plug-ins, or other suitable data structures, and can include two or more different lines of code or suitable data structures operating in two or more separate software applications, on two or more different processing platforms, or in other suitable architectures. In one exemplary embodiment, a software system can include one or more lines of code where coupled other code segments or hardware circuits by passing and/or receiving parameters, arguments or other such data information operating in a general purpose software application, such as an operating system, and one or more lines of code or other suitable software structures operating in a specific purpose software application. In another exemplary embodiment, a software system can be implemented as a distributed software system where parameters, arguments or other such data information may be transmitted, forwarded or passed via a network transmission, memory sharing, token passing, message passing or in other suitable manners.

As illustrated in FIG. 1, additional hardware and network environments in which the transfer-to-practice tools may operate may include a Local Area Network (LAN) 122, a Wide Area Network (WAN) 123. Applicable to a conventional computer or any other type of computer such as network area storage 108 for large file transfer, a remote computer or server 106 can store data from the illustrated programs and modules, relative to processing units within the networked environment by means of the digital devices (102, 103, 104, 105, 300) an/or by means of other wired and/or wireless communications network. However, it is appreciated that the network connections shown are exemplary and other means 109 (i.e. Bluetooth, IEEE 802.11, infrared IT, SIP standards, ZigBee, infrared, mobile communication standard, EV-DO, EV-DO Rev.B, WCDMA, GSM Communication radio, IMT-Advanced cellular systems, cognitive radio, GRID, Cloud, satellite, microwave and communication devices 110 to include, routers, fiber optic cable, a coaxial cable or digital subscriber line (DSL) or DVR, for establishing a communications link between the current system architecture system, devices, methods and computer-readable mediums may be used.

Computer-readable medium and storage of multiple program modules, application programs, and program data, can be carried out on digital versatile disk (DVD) drive 112 for reading from a removable DVD 111, a hard disk drive 112 for reading from and writing to a hard disk and an optical disk drive 113 for reading from or writing to a removable optical disk 114 such as a CD ROM or other optical media. The DVD drive 112, hard disk drive 115 and optical disk drive 214 coupled with respective drive interfaces. Further, laser discs 116, or blu-ray disc 116, magnetic disk storage mediums, read-only memory (ROM), random access memory (RAM), flash memory devices, optical storage mediums, EEPROM, USB, CD-ROM optical, magnetic, or other combinations, within 102, 103, 104, 105, 106, 107, 110, 201A, 201B and other such configurations.

Peripheral input devices such as a keyboard 119, pointing device 118, mouse 123, or where an interface configuration 300 is designed to communicate with voice recognition, touch screen or panel, button, switch, combination, or (a wheel/button roller ball, or trackball, not shown) may be used to enter commands. Further, input devices and ports can include, television 120, a monitor 121 and printer 125.

Referring now to FIG. 9 and FIG. 10 is an illustration of an embodiment of an in-device integrating the tool of FIG. 1 and method of FIG. 2 and FIG. 5A-FIG. 5E. According to one embodiment of the present invention, an in-device 300, preferably configured to be wearable on a user/learner/player (B), or in some circumstances used by a machine. The device 300 operates as wireless communication and includes a display 301, (that can include but is not limited to displays as liquid crystal (LCD), Light emitting device (LED), organic light-emitting diode (OLED), Active-Matrix OLED (AMOLED), phosphorescent organic light-emitting diode (OLED), field emission display (FED), SED (surface-conduction electron-emitter). The display configuration preferably takes into account power requirements, size and space in the actual implementation.

Further speakers 302 for both listening and speaking, an interface unit 303, and a pliable silicon (i.e. miniscule recycled silicon and or polycrystalline and titanium dioxide) package. Processing within 200 by means and/or circuitry configurations of metal (i.e. nano-scaled Au, Ag or near-transparent Au. Further incorporation of a polymer including a fabrication incorporating the hydrogen producing oxidation of DOPA and dopamine (L-3,4-dihydroxyphenylalanine, 3-hydroxytyramine hydrochloride, respectively) for conductors and for the contribution to an enhanced solar cell energy fabrication or configuration. The solar energy source including one or a combination of fabrication or technologies for incorporating solar cells, photovoltaic, quantum dot and or biomimetics, may be enhanced with simple or compound lens prism optics (i.e. a fresnel design).

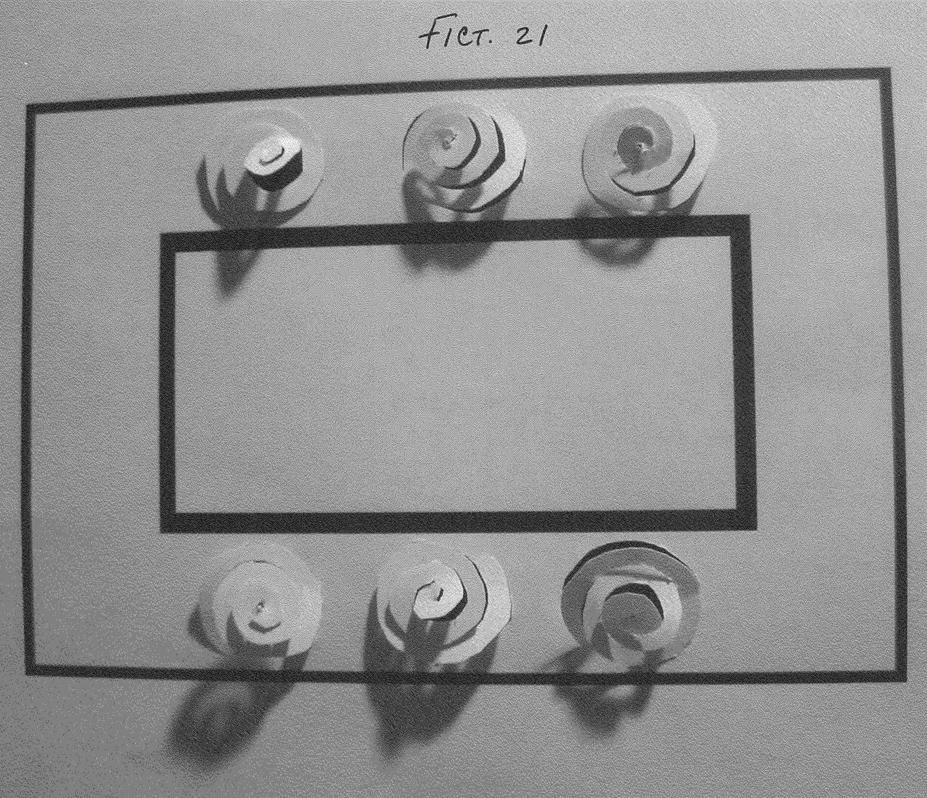

The fresnel prism design may be configured within the anterior surface of the silicone cellulose or collagen face (i.e. 10A) of the device or within the layers of colloidal silicon substrate (i.e. 304) and or between the melanin and polydopamine polymer planes illustrated in FIG. 10B. The DOPA, melanin configuration as noted above is useful wherein the DOPA and melanin polymer configurations are applied in two separate but connected layers and a cold needle perforation is utilized to integrate the two layers in one embodiment. In particularly, as illustrated, in a another embodiment using ink compositions within perforated layers, the resultant configuration is a miniscule suction adhesive formation. Further embodiments that contribute to the fabrication process entail conducive fabricating methods bulk production including spin-casting (i.e. where the mold is dissolvable) and a triple combination of printing, cutting, die-casting for a linear actuator motor FIG. 21 (later described in this paper).

In one embodiment using parallel tool bars (in this embodiment) being the formatting tool bar and the drawing tool bar, the tool bars being equidistant from the centroid of the non-magnetic sheet, the user interacts with the desired widgets being a word command and an image frequency for triggering computations. In another embodiment, within the n-dimensional array of the previously described sobolev spaces, a configured orthogonal projection or plurality of projectious, can be uploaded onto the desired object using a remote server or cloud to see that P is indeed a projection, i.e. P=P2.

In a further embodiment, upon validating the orthogonal projections for the linear actuator motor configuration, the orthogonal projections are either returned to the sender or forwarded onto a fabricator for further processing using a printer or a cutting machine parallel port either locally or to a remote computer or a cloud. When the linear actuator motor configuration is used as a die-casting mold, the configuration is stabilized within a frame whereby the linear actuator motor configuration is placed flat and wherein the projections are extended to enable the reproduction of each helecoid plane. The material or metamaterial of choice is then slowly poured around the linear actuator configuration until the configuration is covered. Upon completion of the drying time for the material or metamaterial of choice, the linear actuator is removed from the mold. The linear actuator motor is then cleaned with a composition appropriate for the material or metamaterial of choice in preparation for assembly.

The operating mode of the linear actuator motor is due to inductance and thrust. In one embodiment, the linear actuator motor can be plated with a metal-loaded ink, where the ink is deposited on the back side of a helecoid where the linear actuator motor is used for medium to large structures. In another embodiment, the linear actuator can be surrounded by a metal-loaded flux in containment with the helecoid, where the linear actuator motor is used for large applications requiring thrust. In a further embodiment, the edges of the helecoid plane can be coated, printed, dipped or other such processes for edging the helecoid plane where the linear actuator motor is used for small structures.

Further motion force, perforation, and in some embodiments low thermal and/or air and integration and UV light curing at between 265 nm and slightly higher than 400 nm for layer and or plane fabrication. However, depending upon the light-matter interaction requirements, all electromagnetic spectrum wavelengths may be integrated when using terahertz radiation. Further, a tesla coil may be used in combination with the compositions in FIG. 10, FIG. 11 and FIG. 12.

Electrochemical Compositions

In a further embodiment, as may be illustrated as in FIGS. 11-12, this invention relates to a process using 3-hydroxytyramine hydrochloride, 3,4-dibydroxy-DL-phenylalaline, NaCl composition containing tyrosinase, copper, carbonate and silica gel in water wherein the aqueous solution where in one embodiment metallotropic liquid crystals form. In a further embodiment, this invention relates to the process using 3-hydroxytyramine hydrochloride, 3,4-dihydroxy-DL-phenylalaline, NaCl composition and silica gel in water to produce a magnetorheological fluid. Still further, this invention relates to polymerized film readily polymerizing on a substrate. Further still, this invention relates to a process of a powdered-coated substrate capable of being reconstituted by the addition of water for portability. Further, the above aspects of the invention can be applied separately or when combined, provide a novel process for self-assembling and consequently self-organizing a bottom-up device fabrication. Still further, the above aspects of the invention can be applied separately or when combined for collecting carbon.

A cellulose altering supermolecular assembly of 3-hydroxytyramine hydrochloride, 3,4-dihydroxy-DL-phenylalaline, NaCl composition containing tyrosinase, carbonate and silica gel in water is advantageously accelerated in the presence of redox isomerizations and dioxygen oxidation reactions involving the 3-hydroxytyramine hydrochloride, 3,4-dihydroxy-DL-phenylalaline for transitioning from acid to base. Also useful are the alkaline enhancing agents of the sodium chloride composition such as potassium, for affecting the dissolution of the silica gel and successive saturation of the alkaline solution and subsequent oligomerization of the aqueous silicate.

The electrochemical-electromagnetic system, of the present invention, begins self-assembling after the dispersion of 3-hydroxytyramine hydrochloride, 3,4-dihydroxy-DL-phenylalaline, NaCl composition containing tyrosinase, copper, carbonate and silica gel in water by stirring. In general, the self-assembling may be carried out in temperatures between 12.7° C. and 29.4° C. within an aqueous and colloid phase.

In one embodiment, NaCl compositions (and inclusions) containing tyrosinase, carbonate, and composed of at least one of elements including,

hydrogen H, 2H (deuterium)

oxygen O,

lithium Li,

beryllium Be,

boron B,

carbon C,

nitrogen N,

fluorine F,

sodium Na,

magnesium Mg,

aluminum Al,

silicon Si,

phosphorous P,

sulfur S,

chloride Cl,

calcium Ca,

scandium Sc,

titanium Ti,

vanadium V,

chromium Cr,

manganese Mn,

iron Fe,

cobalt Co,

nickel Ni,

copper Cu,

zinc Zn,

gallium Ga,

germanium Ge,

arsenic As,

selenium Se,

bromine Br,

rubidium Rb,

strontium Sr,

yttrium Y,

zirconium Zr,

niobium Nb,

molybdenum Mo,

ruthenium Ru,

rhodium Rh,

palladium Pd,

silver Ag,

cadmium Cd,

indium In,

tin Sn,

antimony Sb,

tellurium Te,

iodine I,

cesium Cs,

barium Ba,

lanthanum La,

cerium Ce,

praseodymium Pr,

samarium Sm,

europium Eu,

gadolinium Gd,

terbium Tb,

dysprosium Dy,

holmium Ho,

erbium Er,

thulium Tm,

ytterbium Yb,

lutetium Lu,

hafnium Hf,

tantalum Ta,

tungsten W,

rhenium Re,

osmium Os,

iridium Ir,

platinum Pt,

mercury Hg,

thallium TI,

lead Pb,

bismuth Bi,

thorium Th,

uranium

plutonium Pu,

Krypton K,

Xeon Xe

Neon Ne

Gold Au

Potassium K

Argon Ar

Rhodium Rh

Palladium Pd

Indium In

Tellurium Te

may readily contribute to further kinetic, optical, electrical and all other functional characteristics as well as supermolecular assembly enablement for additional self-assembling, self-organizing and new configurations. In specialized embodiments, neodymium Nd, may also be composed.

In a further embodiment, NaCl compositions containing tyrosinase, copper and carbonate, can be composed of at least one of elements with parts per million (ppm) dust resonances as radiated energy versus wavelength (Siegel, 2002) and atmospheric transmissions in the terahertz region at various locations and altitudes for given water vapor pressure (Siegel, 2002) given as detected or developed equaling mg/litre=0.001 g/kg., where the at least ppm is <, > by 10% or equal to the at least ppm of the elements to include, hydrogen H 110,000 ppm, oxygen O 883,000 ppm, lithium Li 0.170 ppm, beryllium Be 0.0000006 ppm, boron B 4.450 ppm, carbon C 28.0 ppm, nitrogen N ion, 15.5 ppm, fluorine F 13 ppm, sodium Na 10,800 ppm, magnesium Mg 1,290, aluminum Al 0.0001, silicon Si 2.9 ppm, phosphorous P 0.088 ppm, sulfur S 904 ppm, chlorine Cl 19,400 ppm, calcium Ca 411, scandium Sc<0.000004 ppm, titanium Ti 0.001 ppm, vanadium V 0.0019 ppm, chromium Cr 0.0002 ppm, manganese Mn 0.0004 ppm, iron Fe 0.0034 ppm, cobalt Co 0.00039 ppm, nickel Ni, copper Cu 0.0009 ppm, zinc Zn 0.005 ppm, gallium Ga 0.00003 ppm, germanium Ge 0.00006 ppm, arsenic As 0.0026 ppm, selenium Se 0.0009 ppm, bromine Br 67.3 ppm, rubidium Rb 0.120 ppm, strontium Sr 8.1 ppm, yttrium Y 0.000013 ppm, zirconium Zr 0.000026 ppm, niobium Nb 0.000015 ppm, molybdenum Mo 0.01 ppm, ruthenium Ru 0.0000007 ppm, silver Ag 0.00028 ppm, cadmium Cd 0.00011 ppm, tin Sn 0.00081 ppm, antimony Sb 0.00033 ppm, iodine I 0.064, cesium Cs 0.003, barium Ba 0.021 ppm, lanthanum La 0.0000029 ppm, cerium Ce, 0.0000012 ppm praseodymium Pr 0.00000064 ppm, samarium Sm 0.0000028 ppm, europium Eu 0.00000045 ppm, gadolinium Gd 0.0000007 ppm, terbium Tb0.00000014 ppm, dysprosium Dy 0.00000091 ppm holmium Ho 0.00000022 ppm erbium Er, thulium Tm 0.00000017 ppm, ytterbium Yb 0.00000082 ppm, lutetium Lu 0.00000015 ppm, hafnium Hf<0.00000, tantalum Ta<0.0000025, tungsten W<0.000001 ppm, rhenium Re 0.0000084 ppm, mercury Hg 0.00015 ppm, lead Pb 0.00003 ppm, bismuth Bi 0.00002 ppm, uranium U 0.0033 ppm, neptunium Np, Krypton Kr 0.00021 ppm. thorium Th 0.0000004 ppm, gold Au 0.000011 ppm, Potassium K 392, Neon Ne 0.00012 ppm, Argon Ar 0.450 ppm, Xeon Xe 0.000047 ppm, and or negligible Rhodium Rh, Palladium Pd, Indium In, Tellurium Te, Osmium Os, Iridium Ir, Platinum Pt, Thallium Ti, Plutonium Pu; which may readily contribute to further electromagnetic, optical, electrical and all other functional characteristics as well as supermolecular assembly enablement for additional self-assembling, self-organizing and new configurations.

In a still further embodiment, NaCl compositions containing tyrosinase, copper and carbonate can be composed of at least one of elements with parts per million (ppm) dust resonances as radiated energy versus wavelength (Siegel P. H., 2002) and atmospheric transmissions in the terahertz region at various locations and altitudes for given water vapor pressure (Siegel P. H., 2002) equaling mg/litre=0.001 g/kg., where the at least ppm is <, >20% or equal to the at least ppm of the elements to include; hydrogen H 110,000 ppm, oxygen O 883,000 ppm, lithium Li 0.170 ppm, beryllium Be 0.0000006 ppm, boron B 4.450 ppm, carbon C 28.0 ppm, nitrogen N ion, 15.5 ppm, fluorine F 13 ppm, sodium Na 10,800 ppm, magnesium Mg 1,290, aluminum Al 0.0001, silicon Si 2.9 ppm, phosphorous P 0.088 ppm, sulfur S 904 ppm, chlorine Cl 19,400 ppm, calcium Ca 411, scandium Sc<0.000004 ppm, titanium Ti 0.001 ppm, vanadium V 0.0019 ppm, chromium Cr 0.0002 ppm, manganese Mn 0.0004 ppm, iron Fe 0.0034 ppm, cobalt Co 0.00039 ppm, nickel Ni, copper Cu 0.0009 ppm, zinc Zn 0.005 ppm, gallium Ga 0.00003 ppm, germanium Ge 0.00006 ppm, arsenic As 0.0026 ppm, selenium Se 0.0009 ppm, bromine Br 67.3 ppm, rubidium Rb 0.120 ppm, strontium Sr 8.1 ppm, yttrium Y 0.000013 ppm, zirconium Zr 0.000026 ppm, niobium Nb 0.000015 ppm, molybdenum Mo 0.01 ppm, ruthenium Ru 0.0000007 ppm, silver Ag 0.00028 ppm, cadmium Cd 0.00011 ppm, tin Sn 0.00081 ppm, antimony Sb 0.00033 ppm, iodine 10.064, cesium Cs 0.003, barium Ba 0.021 ppm, lanthanum La 0.0000029 ppm, cerium Ce, 0.0000012 ppm praseodymium Pr 0.00000064 ppm, samarium Sm 0.0000028 ppm, europium Eu 0.00000045 ppm, gadolinium Gd 0.0000007 ppm, terbium Tb0.00000014 ppm, dysprosium Dy 0.00000091 ppm holmium Ho 0.00000022 ppm erbium Er, thulium Tm 0.00000017 ppm, ytterbium Yb 0.00000082 ppm, lutetium Lu 0.00000015 ppm, hafnium Hf<0.00000, tantalum Ta<0.0000025, tungsten W<0.000001 ppm, rhenium Re 0.0000084 ppm, mercury Hg 0.00015 ppm, lead Pb 0.00003 ppm, bismuth Bi 0.00002 ppm, uranium U 0.0033 ppm, neptunium Np, Krypton Kr 0.00021 ppm. thorium Th 0.0000004 ppm, gold Au 0.000011 ppm, Potassium K 392, Neon Ne 0.00012 ppm, Argon ar 0.450 ppm, Xeon Xe 0.000047 ppm, and or negligible Rhodium Rh, Palladium Pd, Indium In, Tellurium Te, Osmium Os, Iridium Ir, Platinum Pt, Thallium Tl, Plutonium Pu;

resultant within the self-organization of the supermolecular assembly 3-hydroxytyramine hydrochloride, 3,4-dihydroxy-DL-phenylalaline, NaCl composition containing tyrosinase, carbonate and silica gel in water, which may readily contribute to further kinetic (i.e. particle), optical, electrical and all other functional characteristics as well as supermolecular assembly enablement for additional self-assembling, self-organizing and new configurations.

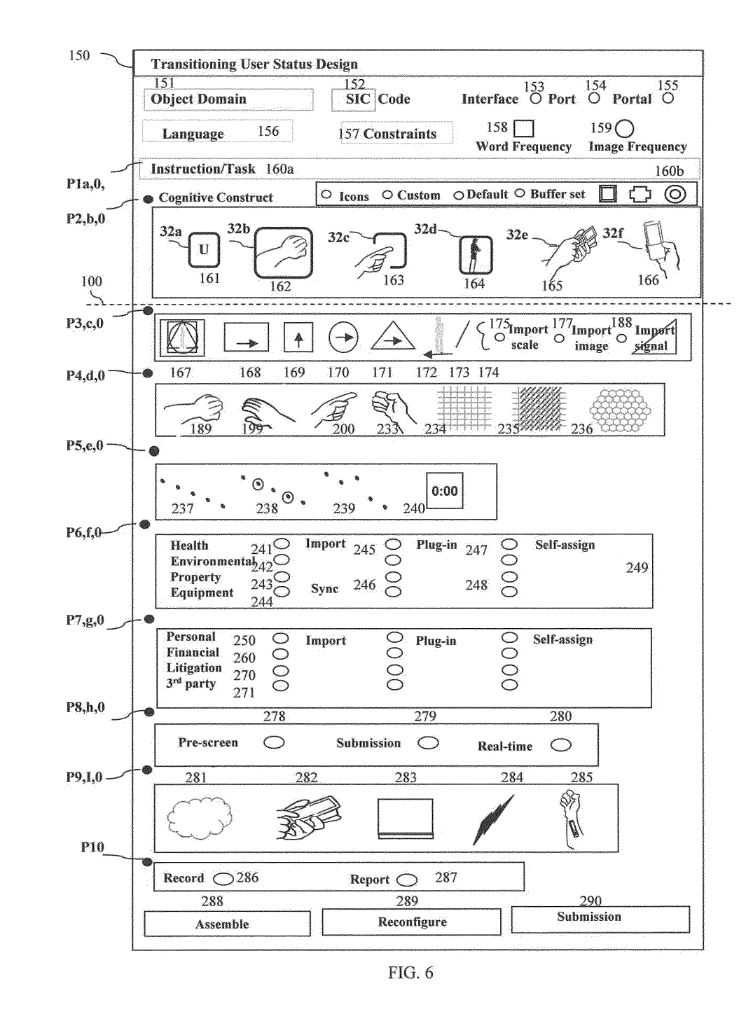

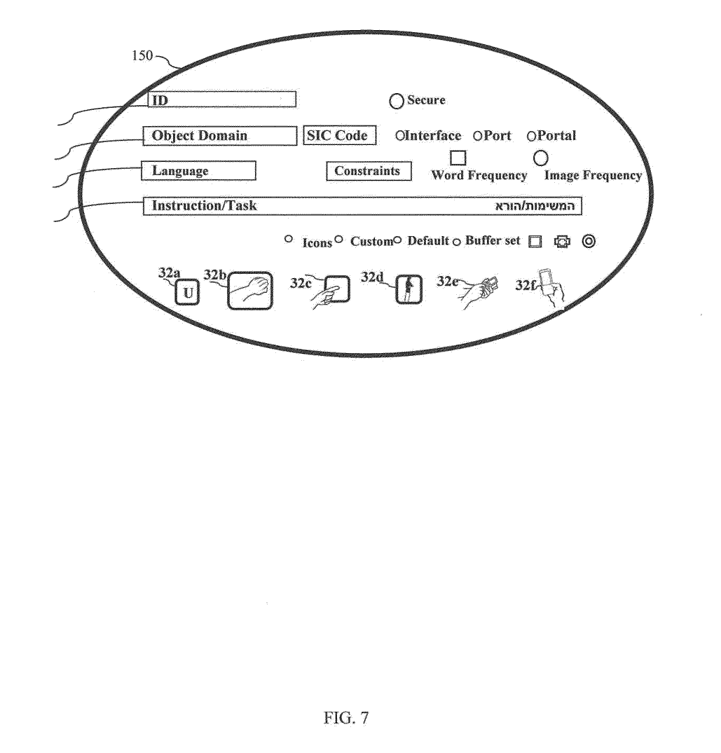

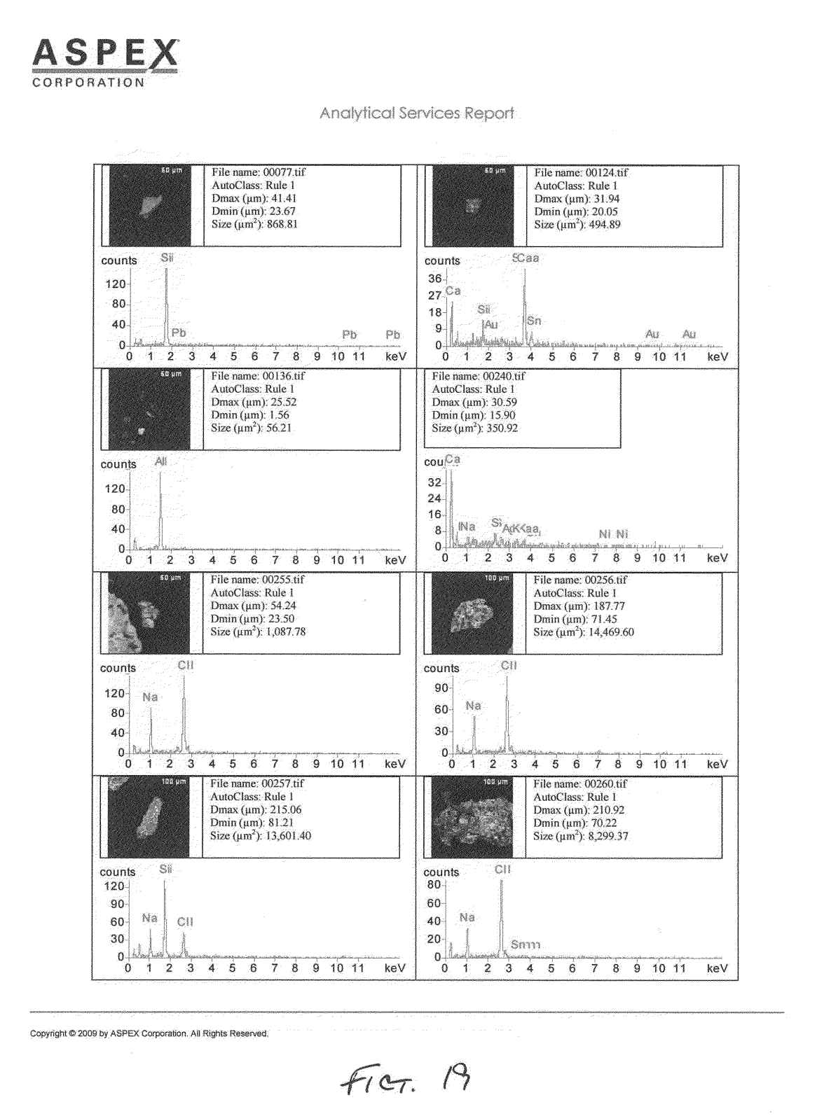

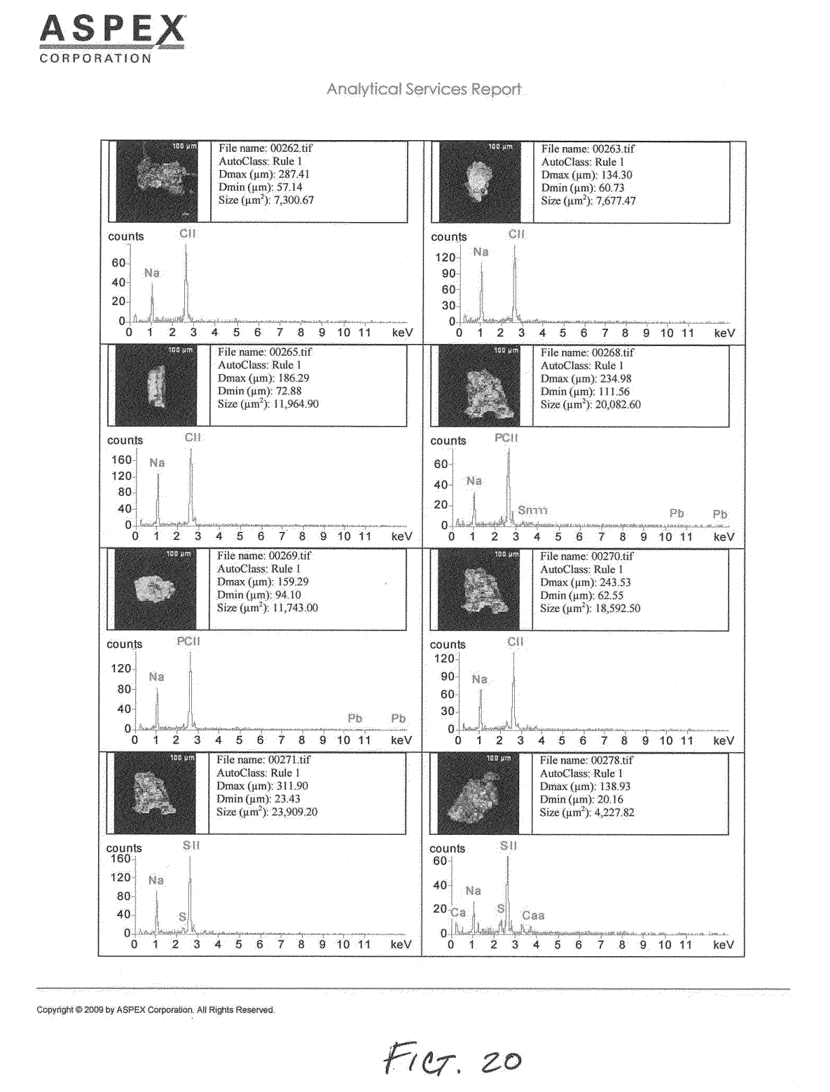

The following examples serve to illustrate the process of the present invention and the cellulose altering supermolecular assembly produced thereby that may be utilized as illustrated in FIG. 2, FIG. 3, FIG. 4, FIG. 5, FIG. 6, FIG. 7, FIG. 8, FIG. 9, FIG. 10, FIG. 11, FIG. 12, FIG. 19, and FIG. 20. The parts by weight have the same relationship to parts by volume as grams to milliliters.

### EXAMPLE 1

Equal parts by weight of 3-hydroxytyramine hydrochloride, 3,4-dihydroxy-DL-phenylalaline were dispersed in 3 parts by weight of water and 12% weight by volume NaCl composition containing tyrosinase, copper and carbonate, in the presence of 15% weight by volume sodium silicate beads (1.5 mm). In one embodiment, the gram weight of the example includes, 0.0150 g. 3,4-dihydroxy-DL-phenylalaline, 0009 g.3-hydroxytyramine hydrochloride, 0.1008 g. silica gel beads, 0.0265 g. NaCl composition containing trace tyrosinase, trace copper, carbonate and 0.6250 water.

The initially translucent aqueous solution tinted very pale yellow surrounding the area of the silica gel bead dispersion into the solution upon initiating the silica gel dissolution. Further, the initially translucent aqueous solution tinted pink grey within the grayscale during the first hour upon introduction of the 3-hydroxytyramine hydrochloride, 3,4-dihydroxy-DL-phenylalaline and increased in grayscale to a black coloration over an 18 hr period.

An initially very small amount of white suspensions of the 3-hydroxytyramine hydrochloride, 3,4-dihydroxy-DL-phenylalaline (μm²) began turning black within 15 minutes. After an hour the amount of black suspensions doubled in number and continued to increase in amount and black color intensity over a 18 hr period. The suspensions exhibited a slight repulsion characteristic as a consequence of coming in contact with a magnetic field. Metal suspension within both the aqueous and colloid solutions as a consequence of the NaCl composition to include at least: Na, Cu, Sn, Mg, K, Ca, Al, Au, Ag, Pb, Ni, (as sample analysis detected in BSED images in Appendix A), may readily contribute to this observation, and the resultant cholesteric liquid crystal phase.

### EXAMPLE 2

### Self-organizing Metallotropic Liquid Crystals

In a further embodiment, equal parts by weight of 3-hydroxytyramine hydrochloride, 3,4-dihydroxy-DL-phenylalaline are dispersed in 3 parts by volume of water and a 12-24% weight by volume NaCl composition containing tyrosinase, copper and carbonate, in the presence of a 15% weight by volume silica gel, may readily provide for surfactant templating nanometer size 3-hydroxytyramine hydrochloride, 3,4-dihydroxy-DL-phenylataline, NaCl composition dispersed within the reaction mixture for self-organizing metallotropic liquid crystals. Preferably, the metallotropic liquid crystals are collected within a 1-5 hr self-organizing period.

### EXAMPLE 3

In a still further embodiment, equal parts by weight of 3-hydroxytyramine hydrochloride, 3,4-dihydroxy-DL-phenylalaline are dispersed in 3 parts by volume of water and a 12-35% weight by volume NaCl composition containing tyrosinase, copper and carbonate, in the presence of a 15% weight by volume silica gel may readily provide for surfactant templating nanometer size 3-hydroxytyramine hydrochloride, 3,4-dihydroxy-DL-phenylalaline, NaCl composition dispersed within the reaction mixture for self-organizing metallotropic liquid crystals. Preferably, the metallotropic liquid crystals are collected within a 1-4 hr self-organizing period.

### EXAMPLE 4

In a further embodiment, equal parts by weight of 3-hydroxytyramine hydrochloride, 3,4-dihydroxy-DL-phenylalaline are dispersed in 3 parts by volume of water and a 0.5-35% weight by volume NaCl composition containing tyrosinas, copper and carbonate, in the presence of a 15% weight by volume silica gel, may readily provide for surfactant templating nanometer size 3-hydroxytyramine hydrochloride, 3,4-dihydroxy-DL-phenylalaline, NaCl composition dispersed within the reaction mixture for self-organizing metallotropic liquid crystals. Preferably, the metallotropic liquid crystals are collected within a 1-8 hr self-organizing period.

### EXAMPLE 5

Self-organizing Magnetorheological Fluid

In another embodiment, equal parts by weight of 3-hydroxytyramine hydrochloride, 3,4-dihydroxy-DL-phenylalaline are dispersed in 3 parts by volume of water and a 12-24% weight by volume NaCl composition containing tyrosinase, copper and carbonate, in the presence of a 15% weight by volume silica gel, may readily provide for micro-encapsulation of the micrometer size particles of the 3-hydroxytyramine hydrochloride, 3,4-dihydroxy-DL-phenylalaline, NaCl composition dispersed within the reaction mixture for self-organizing magnetorheological fluid using a sunflower oil or a miscible composition. Preferably, the magnetorheological fluid is collected within a 6-18 hr self-organizing period.

### EXAMPLE 6

In a further embodiment, equal parts by weight of 3-hydroxytyramine hydrochloride, 3,4-dihydroxy-DL-phenylalaline are dispersed in 3 parts by volume of water and a 12-35% weight by volume NaCl composition containing tyrosinase, copper and carbonate, in the presence of a 15% weight by volume silica gel, may readily provide for micro-encapsulation of the micrometer size particles of the 3-hydroxytyramine hydrochloride, 3,4-dihydroxy-DL-phenylalaline, NaCl composition dispersed within the reaction mixture for self-organizing magnetorheological fluid when using a sunflower oil or a miscible composition. An 18 gauge copper wire that had been annealed at temperatures between 180 and 200 degrees and then cooled was placed in a unclosed loop form shaped to bottom of a circular plastic container. Preferably, the magnetorheological fluid is collected within a 6-15 hr. self-organizing period.

### EXAMPLE 7

In a further embodiment, equal parts by weight of 3-hydroxytyramine hydrochloride, 3,4-dihydroxy-DL-phenylalaline are dispersed in 3 parts by volume of water and a 0.5-35% weight by volume NaCl composition containing tyrosinase and carbonate, in the presence of a 15% weight by volume silica gel, may readily provide for micro-encapsulation of the micrometer size particles of the 3-hydroxytyramine hydrochloride, 3,4-dihydroxy-DL-phenylalaline, NaCl composition dispersed within the reaction mixture for self-organizing magnetorheological fluid using sunflower oil or a miscible composition. Preferably, the magnetorheological fluid is collected within a 6-24 hr self-organizing period.

### EXAMPLE 8

Self-Organizing Polymerization on a Substrate

In another embodiment, equal parts by weight of 3-hydroxytyramine hydrochloride, 3,4-dihydroxy-DL-phenylalaline are dispersed in 4 parts by volume of water and a 12-24% weight by volume NaCl composition containing tyrosinase, copper and carbonate, in the presence of a 30% weight by volume silica gel may readily provide for the polymerization of the 3-hydroxytyramine hydrochloride, 3,4-dihydroxy-DL-phenylalaline, NaCl and the aqueous silica solution for self-organizing polymerization on a substrate. Preferably, the polymerization on a substrate is collected within a 18 hr self-organizing period when natural drying is permitted.

### EXAMPLE 9

In another embodiment, equal parts by weight of 3-hydroxytyramine hydrochloride, 3,4-dihydroxy-DL-phenylalaline are dispersed in 4 parts by volume of water and a 12-35% weight by volume NaCl composition containing tyrosinase, copper and carbonate, in the presence of a 30% weight by volume silica gel may readily provide for the polymerization of the 3-hydroxytyramine hydrochloride, 3,4-dihydroxy-DL-phenylalaline, NaCl composition containing tyrosinase and the aqueous silica solution for self-organizing polymerization on a substrate. An 18 gauge copper wire that had been annealed at temperatures between 180 and 200 degrees and then cooled was placed in a unclosed loop form shaped to the bottom of a circular plastic container. Preferably, the polymerization on a substrate is collected within a 17 hr self-organizing period when natural drying is permitted.

### EXAMPLE 10

In another embodiment, equal parts by weight of 3-hydroxytyramine hydrochloride, 3,4-dihydroxy-DL-phenylalaline are dispersed in 4 parts by volume of water and a 0.5-35% weight by volume NaCl composition containing tyrosinase, copper and carbonate, in the presence of a 30% weight by volume silica gel and a copper wire encircled on the bottom of the container, may readily provide for the polymerization of the 3-hydroxytyramine hydrochloride, 3,4-dihydroxy-DL-phenylalaline, NaCl and the aqueous silica solution for self-organizing polymerization on a substrate. Preferably, the polymerization on a substrate is collected within a 18-36 hr self-organizing period when natural drying is permitted.

### EXAMPLE 11

Reconstituted Metallotropic Liquid Crystals and Magnetorheological Particles

In another embodiment, equal parts by weight of 3-hydroxytyramine hydrochloride, 3,4-dihydroxy-DL-phenylalaline are dispersed in 3 parts by volume of water and a 0.5-35% weight by volume NaCl composition containing tyrosinase, copper and carbonate, in the presence of a 15% weight by volume silica gel and a copper wire encircled on the bottom of the container, may readily provide for micro-encapsulation of the micrometer size particles of the 3-hydroxytyramine hydrochloride, 3,4-dihydroxy-DL-phenylalaline, NaCl composition dispersed within the reaction mixture for self-organizing metallotropic liquid crystals and magnetorheological particles for use in a Smart dust or a Speck configuration. Preferably, the metallotropic liquid crystals and the magnetorheological particles as a powdered-coated substrate are reconstituted by the addition of water after a>24 hr self-organizing period.

### EXAMPLE 12

Within a further embodiment, equal parts by weight of 3-hydroxytyramine hydrochloride, 3,4-dihydroxy-DL-phenylalaline are dispersed in 3 parts by volume of water and a 0.5-35% weight by volume NaCl composition containing tyrosinase, copper and carbonate, in the presence of a 15% weight by volume silica gel, may readily provide for micro-encapsulation of the micrometer size particles of the 3-hydroxytyramine hydrochloride, 3,4-dihydroxy-DL-phenylalaline, NaCl composition dispersed within the reaction mixture for self-organizing metallotropic liquid crystals and magnetorheological particles for use in a Smart dust or a Speck configuration. Preferably, the metallotropic liquid crystals and the magnetorheological particles as a powdered-coated substrate are reconstituted by the addition of water after a>24 hr self-organizing period when allowed to dry naturally.

### EXAMPLE 13

Nanometer Absorption Within a Core

In a further embodiment, equal parts by weight of 3-hydroxytyramine hydrochloride, 3,4-dihydroxy-DL-phenylalaline are dispersed in 3 parts by volume of water and a 12% weight by volume NaCl composition containing tyrosinase, copper and carbonate, in the presence of a 15% weight by volume silica gel, may provide for the absorption of nanometer size 3-hydroxytyramine hydrochloride, 3,4-dihydroxy-DL-phenylalaline, NaCl composition within a core. Preferably, the core is collected within a 1-3 hr self-organizing period.

### EXAMPLE 14

In particularly, in a further embodiment for the electrochemical compositions 1 and electrochemical compositions 2 a slight repulsion characteristic was observed when a polyethylene bag containing the above noted suspensions (now black dust) came in contact with a magnetic field. In a further embodiment, the previously observed repulsion characteristic continued to be observed in a resultant black-semi transparent glass when also coming in contact with a magnetic field. In a still further embodiment, the previously observed repulsion characteristic continued to be observed when the black dust on a plastic/paper substrate also come in contact with a magnetic field. The slight repulsion characteristic is useful for providing protective forces when encountering unexpected and unwanted electromagnetic effects (i.e. an electronic component, a display or monitor or a substrate primarily used outdoors).

### EXAMPLE 15

a Miscible Composition

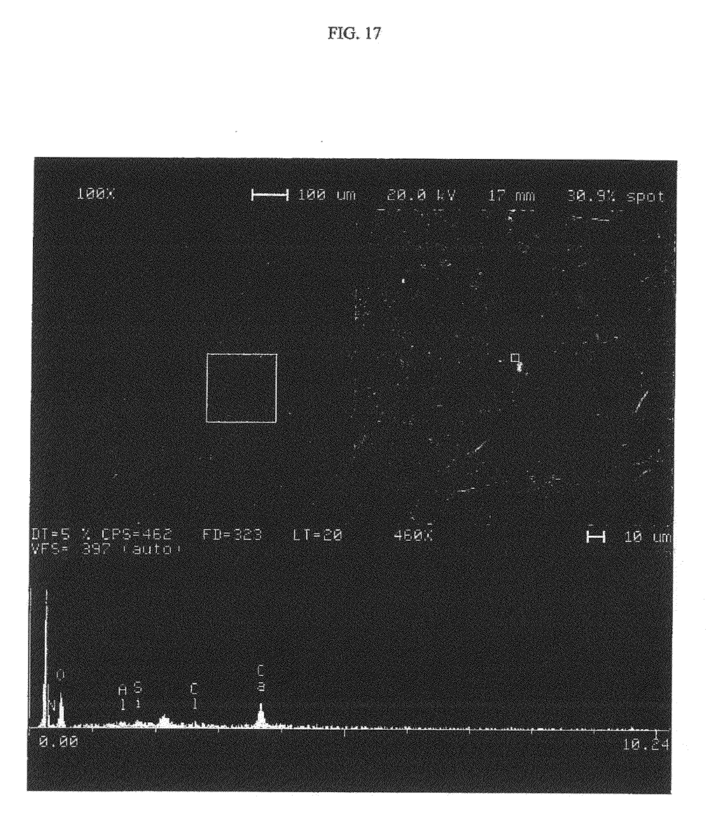

In a further embodiment, equal parts by weight of 3-hydroxytyramine hydrochloride, 3,4-dihydroxy-DL-phenylalaline are dispersed in 3 parts by volume of water and a 12% weight by volume NaCl composition containing tyrosinase, copper and carbonate, in the presence of 15% weight by volume silica gel in an open plastic container for 2 days. The aqueous solution is then placed in a second plastic container partially coated on the inside with aluminum where the aluminum is in partial contact with the aqueous solution and where a polyethylene substrate surfaced with a miniscule paraffin layer and backed to a cellulose layer is in contact with the aqueous solution. In three of the days, steam is applied to the plastic container for two sessions of 8-12 minutes. For the last two days the aqueous solution is enclosed. After the seventh day, a resultant glossy, black miscibile composition is formed on the polyethylene/cellulose substrate and walls of the plastic container. Still further, is the resultant carbon fiber formation grown on the polyethylene/cellulose substrate (as sample analysis detected in SEM/EDS images in FIG. 17 in which the resultant composition contained at least C, N, O, Al, Si, Cl, and Ca). Not wishing to be limited by theory, it is believed it is achieved by the exothermic reaction of the melanin, DOPA, NaCl composition containing tyrosinase, copper, carbonate and silica gel in water.

The above described flexibility is beneficial for enabling the production of more cost effective and user efficient tools. Non-limited applications integrating the aforementioned self-assembling, self-organizing components with the system architecture and/or fabrication, manufacturing process (i.e. which may include printable personalization, utilizing an electrochemical composition as an ink or toner) may include as an exemplary embodiment a throw-away interactive interface for instructing a user on a step-by-step process where in addition to the presentation of an instruction in visual or audio means, some embodiments can enable the receiving of an image or capturing of an image.

Further depending upon the placement of the keys (i.e. FIG. 9D (i.e. 304) or FIG. 9E or F, a user may utilize raised keys where necessary) exemplary embodiments may include, an embodiment for wearable mini-game patches for game and/or instruction interaction between a first user and a second user, a first user and a group of users, a first user and a machine, a first user and an static or dynamic object, a first user and/or an animal and during a running, rolling, spinning, jumping, kicking or swinging, walking or any type of limb or head movement;

another exemplary embodiment, is an indevice for viewing a human impairment,

another exemplary embodiment is a gel remote control;

another exemplary embodiment is a “stick-on-push-to-talk” useful for communication between a child and parent in a temporary location or between a health impaired individual and a caregiver,

another exemplary embodiment is an attachable moisture detection and notification stripping for indicating human fluid leakage onto clothing;

another exemplary embodiment is disposable scanning strips for collecting required information for submitting an uncertainty submission in which in one exemplary embodiment a drawing illustration for a patent application can be scanned for unacceptability, and

a still further exemplary embodiment is a customizable biometric capturing indevice for executing or implementing a cognizance challenge.

### EXAMPLE 17

The chemical system of a further embodiment begins self-assembling after the dispersion of Na₂(HO)₂C₆H₃CH₂CH(NH₂)COOHCl, 3-hydroxytyramine hydrochloride, NaCl composition and 2NaCl as an inclusion, tyrosinase, copper, carbonate and silica gel in water by a gentle rotation and stirring agitation. In general, the self-assembling may be carried out in temperatures between 12.7° C. and 29.4° C. within an aqueous and colloid phase.

### EXAMPLE 18

Equal parts by volume of Na₂(HO)₂C₆H₃CH₂CH(NH₂)COOHCl and 3-hydroxytyramine hydrochloride, NaCl composition and 2NaCl as an inclusion, were dispersed in 1 part by volume of water in the presence of 12% weight by volume halite composition containing tyrosinase, copper and carbonate in the presence of 15% weight by volume sodium silicate beads (1.5 mm). In one embodiment, the gram weight of the example includes, 0.0150 g. Na₂(HO)₂C₆H₃CH₂CH(NH₂)COOHCl, 0.0009 g. 3-hydroxytyramine hydrochloride, 0.1008 g. silica gel beads, 0.0265 g. 2NaCl composition, trace tyrosinase, trace copper, carbonate and 0.6250 water.

The initially translucent aqueous solution tinted very pale yellow surrounding the area of the silica gel bead dispersion into the solution upon initiating the silica gel dissolution. Further, the initially translucent aqueous solution tinted pink-gray readily after introduction of 3-hydroxytyramine hydrochloride, NaCl composition and 2NaCl as an inclusion, tyrosinase, copper, carbonate and silica gel beads to the Na₂(HO)₂C₆H₃CH₂CH(NH₂)COOHCl and water aqueous solution and thereafter increased in grayscale coloration to black over an at least 18 hr period. The pink-gray coloration is consistent with findings reported by Jaber and Lambert, 2010, Ito, S. et. al., 2008, Land, E. J. et. al., 2003 and d'Ischia, M. et. al. 2009 relative to oxidation.

An initially small amount of white suspensions of the Na₂(HO)₂C₆H₃CH₂CH(NH₂)COOHCl, 3-hydroxytyramine hydrochloride, (μm²) began turning black within 15 minutes. After an hour the amount of black suspensions doubled in number and continued to increase in amount and black color intensity over a 18 hr period. The suspensions exhibited a slight repulsion characteristic as a consequence of coming in contact with a magnetic field.

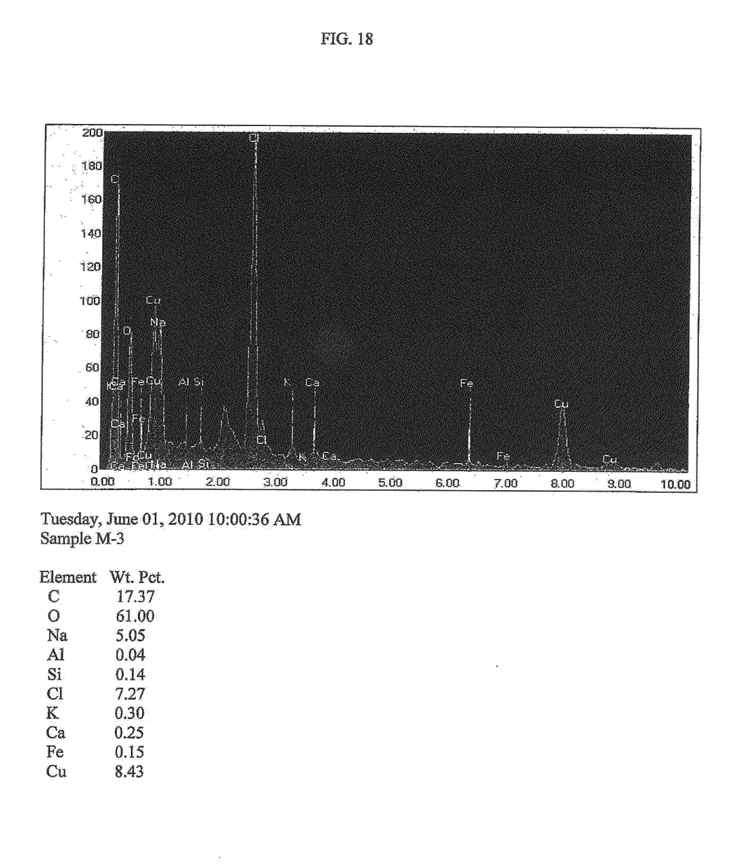

Metal suspension within both the aqueous and colloid solutions as a consequence of the halite composition to include at least: Na, Cu, Mg, K, Ca, Al, Au, Ag, Fe, Pb (as sample analysis detected in BSED images FIG. 19 and FIG. 20), may readily contribute to this observation, and the resultant cholesteric liquid crystal phase. Further, carbon (i.e. 17%) and especially oxygen (i.e. 61%) (as sample analysis detected in SEM/EDS images in FIG. 18) were reported in the polymerization product.

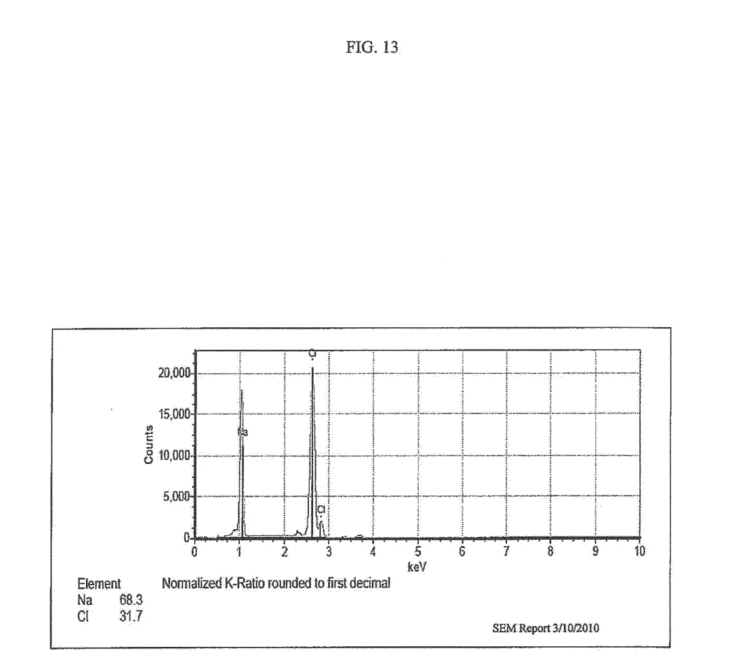

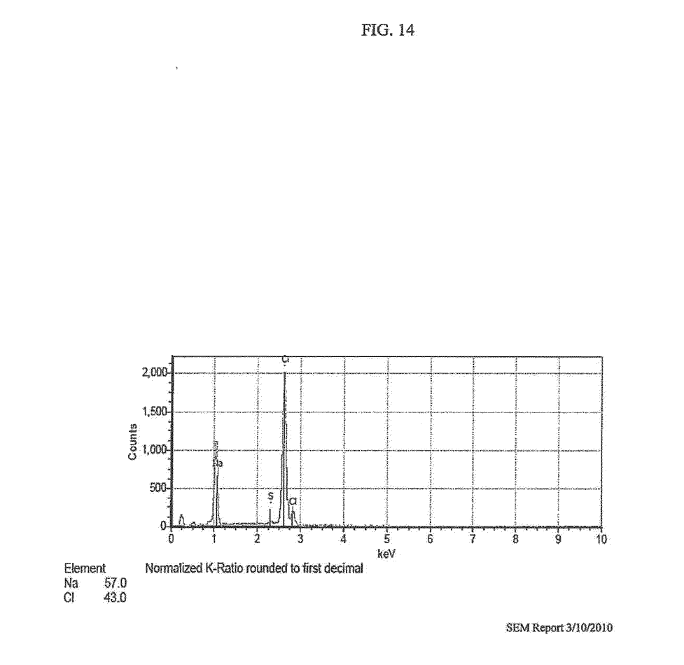

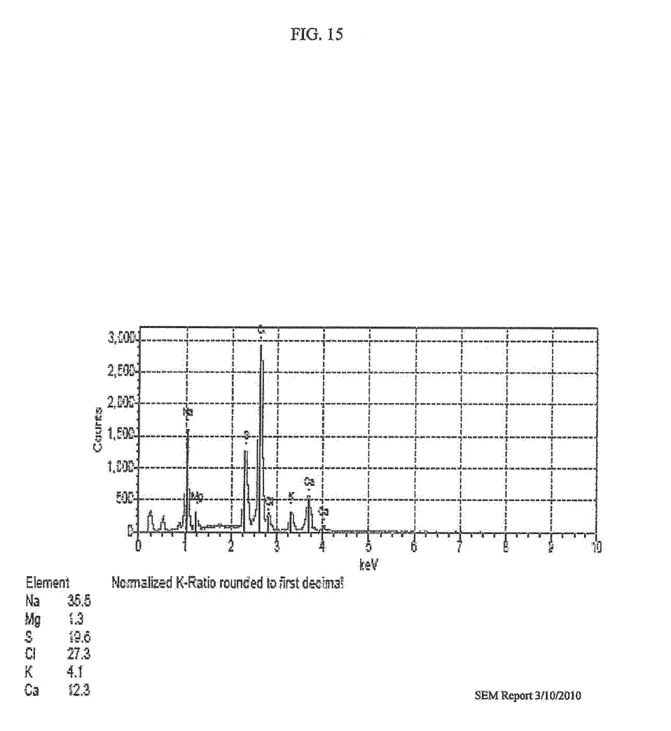

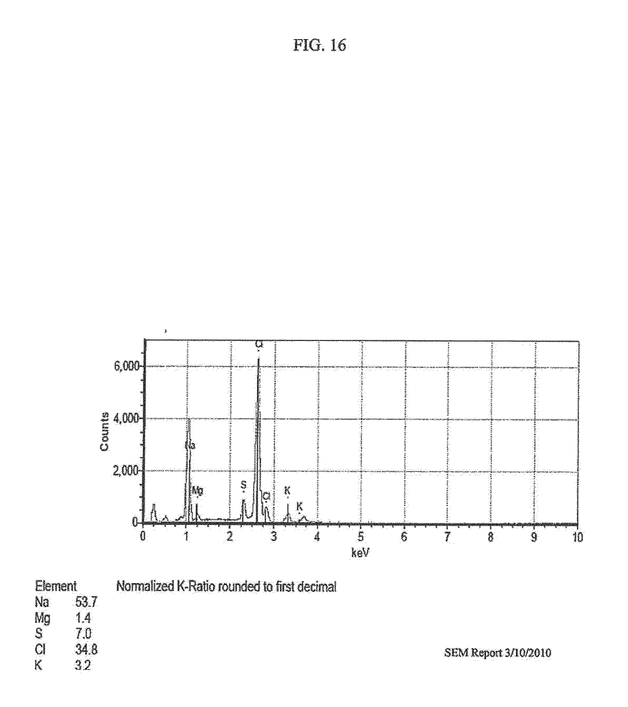

In another embodiment, the NaCl may contained 68.7% sodium and 31.7% chloride (as sample analysis detected in BSED images in FIG. 13). In another embodiment, 2NaCl may contain 57.0% sodium and 43.0% chloride (as sample analysis detected in BSED images in FIG. 14).

Further, in one embodiment, NaCl composition containing tyrosinase may include at least initial self-assembling element percentages at 51% chloride, 35% sodium, 0.82% sulfur, 0.23% potassium, 0.13% calcium, 0.05% silicon, 0.05% carbon, 0.01% iron, 0.01% aluminum, trace copper, negligible magnesium as well as trace zinc (as residual sample analysis detected in BSED images in FIG. 14) and vapor.

Still further in another embodiment, NaCl composition containing tyrosinase may include at least initial self-assembling element percentages at 0.16% calcium, 0.15% magnesium, 0.61% sulphate, 0.001% iron, 0.02% vapor and 0.044% insoluble matter (e.g. clay, red silt, kaolin, kaolite) and 98.62% sodium chloride.

### EXAMPLE 19

Accordingly, a modified growth recipe for graphene includes, 0.0150 g. 3,4-dihydroxy-DL-phenylalaline, 0009 g. 3-hydroxytyramine hydrochloride, 0.1008 g. silica gel beads, 0.0265 g. NaCl composition containing trace tyrosinase, trace copper, carbonate and 0.6250 water grown on 0.025 mm copper foil. Further, the above described flexibility of productions, fabrications and usages of electrochemical compositions 1 and electrochemical compositions 2 and the miscible composition are beneficial for enabling the production of more cost effective and user efficient devices and resources. In particular for one embodiment of the present invention, utilizing the growth recipe for graphene for fabricating a silicon photovoltaic (PV) array. Here, a silicon PV array with a square area of (0.1″×1.0″). can be fabricated having 10% conversation efficiency, with the ability to produce 7 milliwatts of electrical power (3 v at 2.3 ma), based on the assumption of exposure to a one sun light condition. Even with a variable (e.g. 140 microwatts of electrical power or 3 v at 50 microamps DC) the silicon PV array could be used. In comparison, most common RFID chips require about 100 microwatts RMS to operate (2 v at 50 uA DC).

In one embodiment, fabrication techniques can include the technique of Esen and Fuhrer (2011) and similar to Strachan (2005). In particularly, as it relates to the present invention, the technique is useful when integrating gold and lift-off on SiO2. The steps include: measuring a reference conductance value at a voltage of 100 mV; increasing the voltage until the conductance drops by a set fraction of the reference conductance value; when the voltage has decreased 50 to 100 mV a new reference conductance value is measured and the process is repeated. Equipment utilized in the process include conventional electron beam lithography in a no adhesion fabrication technique relative to contacts and bonding pads (to control electromigration) and a computer controlled feedback scheme.

Further, non-limited applications integrating the aforementioned self-assembling, self-organizing electrochemical compositions 1 and 2, miscible composition, growth recipe for graphene resulting in products (i.e. dust, glossy miscible polymer, black translucent glass, loaded-metal inks) with a weak repulsion characteristic when coming in contact with a magnetic field. Further, the resultant products were produced at ambient temperatures. In particularly, the loaded-metal inks are useful in semiconductor fabrication.

Design Tool

A customization/development functionality is provided by accessing the code generator within the core architecture by means of an interface based on vectors. The illustration in FIG. 6, shows, in this instance, a user graphical user interface (GUI) 150.

When GUI 150 is accessed within the RMK 30, only the upper portion “U”, of the GUI 150 appears within the RMK 30 as illustrated in FIG. 7. The GUI 150, provides dialogue boxes for instruction entry 151F, and when within assigned transfer tools, morphological configurations can be selected to display parameter and dimensions individually at P2,0-P10, 0 and 2,1-10,2) and 151H for customized configuration.

When GUI 101 is directly accessed, the vector-based GUI 151, can provide dialogues for instruction entry 151F by means of text, signal or iconic interactions. For example, when the port/portal button 41D is selected, mapping to selected configurations for preferred network access and peripherals is displayed. The SIC (Standard Industrial Classification) code use for supplier scheduling (i.e. for use in an exemplary production enterprise incorporating the system architecture within a solar powered GRID or stand-alone photovoltaic power system (where the next authorized supplier is provided work if the prior supplier is busy or found to not be authorized to receive the scheduled work). When the determining parameter and relative dimension button at 151G is selected, the user is presented with a menu of determining parameters and dimensions (P2,0-P10, 0 and 2,1-10,2) as determined by energy resource. Here, these types of systems may use solar panels only or may be used in conjunction with a diesel generator or a wind turbine.

Similarly, defined morphological configurations can be selected to display parameter and dimensions individually at P2,0-P10, 0 and 2,1-10,2) and 41H, respectively. In particularly, appropriate performance parameters need to be selected and their values consistently updated with each new report. En some cases it may be beneficial to monitor the performance of individual components in order to refine and improve system performance, or be alerted to loss of performance in time for preventative action. For example, monitoring battery charge/discharge profiles using terahertz radiation signaling when replacement is due.

Monitoring photovoltaic systems can provide useful information about their operation and what should be done to improve performance, but if the data are not reported properly, the effort is wasted. In particularly, relevant data parameters are: energy storage capacity and autonomy to store energy when there is an excess available and to provide it when required; voltage and current stabilization to provide stable current and voltage by eradicating transients; and supply surge currents to provide surge currents to loads like motors when required.

Here, holomorphic functions, in particularly the Sobolev spaces are used for measuring the energy of a temperature or velocity distribution by an L²-norm and as a development tool for differentiating Lebesgue functions where the Lebesgue constants (depending its angle preservation) give an idea of bow good the interpolant of a function (at the given nodes) is in comparison with the best polynomial approximation of the function (the degree of the polynomials are obviously fixed).

In another embodiment, the polynomials are used to form polynomial equations for encoding words, chemistry, physics, economics, social science, numerical analysis to approximate other functions, polynomial rings and abstract algebra and abstract geometry for new developments. For example, in linear algebra and functional analysis, a projection is a linear transformation P from a vector space to itself such that P²=P. It leaves its image unchanged.^{[1]} Though abstract, this definition of “projection” formalizes and generalizes the idea of graphical projection. One can also consider the effect of a projection on a geometrical object by examining the effect of the projection on points in the object transformation P where P is orthogonal projection onto the line m. In one embodiment of this invention, the orthogonal projection function maps the point (x, y, z) in three-dimensional space R³ to the point (x, y, 0) is a projection onto the x-y plane. This function is represented by the matrix on an arbitrary vector is

$$P ( \begin{matrix}x \\ y \\ z\end{matrix} ) = ( \begin{matrix}x \\ y \\ 0\end{matrix} )$$

To see that P is indeed a projection, i.e., P=P², for example, link to a remote server or cloud.

Basically, the development GUI 150, provides the user(s) with the capability to generate configurations for transfer components and tools. By means of user manipulation, morphological configurations within blocks and/or modules, facilitate the generation of component configurations.

A simple example of a non-orthogonal (oblique) projection is proving that P is indeed a projection. The projection P is orthogonal if and only if [symbol] =0. Where

λ(A)ij=(λA)ij=λAij

explicitly:

$$λ A = λ ( \begin{matrix}{A}_{11} & {A}_{12} & … & {A}_{1 m} \\ {A}_{21} & {A}_{22} & … & {A}_{2 m} \\ ⋮ & ⋮ & ⋱ & ⋮ \\ {A}_{n 1} & {A}_{n 2} & … & {A}_{nm}\end{matrix} ) = ( \begin{matrix}λ {A}_{11} & λ {A}_{12} & … & λ {A}_{1 m} \\ λ {A}_{21} & λ {A}_{22} & … & λ {A}_{2 m} \\ ⋮ & ⋮ & ⋱ & ⋮ \\ λ {A}_{n 1} & λ {A}_{n 2} & … & λ {A}_{nm}\end{matrix} )$$

file name or web address (http:// . . . ).

GUI 150 is operable and conformational to the core architecture. The core architecture comprises one at least three n-dimensional arrays generated from processing methods of a morphological analysis algorithm (MAA), based on Fritz Zwicky, 1957 and 1969 herein incorporated, in which components of number theory, geometry and visualization are integrated are further utilized for configuring for a quantum.

More formally, a map,

∫:U→V

is called conformal at μ0 if it preserves oriented angles between curves through μ0 with relative to their orientation. Conformal maps preserve both angles and the shapes of infinitesimally small figures, but not necessarily their size. The conformal property may be described in terms of the Jacobian derivative matrix of a coordinate transformation. If the Jacobian matrix of the transformation is everywhere a scalar times a rotation matrix computed as

$$R = [ \begin{matrix}cos θ & - sin θ \\ sin θ & cos θ\end{matrix} ] .$$

In linear algebra an n-by-n (square) matrix A is called invertible if there exists an n-by-n matrix B such that the n-by-n identity matrix and the multiplication used is ordinary matrix multiplication. In this case, the matrix B is uniquely determined by A and is called the inverse of A, denoted by A⁻¹. It follows from the AB=I for finite square matrices A and B, then also BA=I.

Non-square matrices in-by-n matrices may have an inverse computed using a vector equation where each unknown is a weight linearly independent.

$${x}_{1} [ \begin{matrix}{a}_{11} \\ {a}_{21} \\ ⋮ \\ {a}_{m 1}\end{matrix} ] + {x}_{2} [ \begin{matrix}{a}_{12} \\ {a}_{22} \\ ⋮ \\ {a}_{m 2}\end{matrix} ] + … + {x}_{n} [ \begin{matrix}{a}_{1 n} \\ {a}_{2 n} \\ ⋮ \\ {a}_{mn}\end{matrix} ] = [ \begin{matrix}{b}_{1} \\ {b}_{2} \\ ⋮ \\ {b}_{m}\end{matrix} ]$$

The vector equation is equivalent to a matrix equation of the form of vectors in a basis for the span is now expressed as the rank of the matrix where for example, many constructions in mathematics which would be functors but for the fact that they “turn morphisms around” and “reverse composition”. A contravariant functor F from C to D as a mapping that associates to each morphism

f:X→YεC a morphism

F(id_{X})=id_{F(X)} for every object XεC,

F(g∘f)=F(f)∘F(y) for all morphisms f:X→Y and g:Y→Z.

Note that contravariant functors reverse the direction of composition.

In one embodiment of the invention for iterative feedback, the system incorporates an architecture for any component or extended system of the afore described core architecture where the architecture uses a cyclic process for informing an evolving successive versions using ring homomorphism defined

$$A = {⊕}_{n ∈ 0} {A}_{n} = {A}_{0} ⊕ {A}_{1} ⊕ {A}_{2} ⊕ …$$

such that the ring multiplication satisfies

xεAₛ, yεAᵣ [symbol] xyεAₛ₊ᵣ

and so

AₛAᵣ⊂Aₛ₊ᵣ.

Each element described would have to be in every left ideal containing X, so this left ideal is in fact the left ideal generated by X. The right ideal and ideal generated by X can also be expressed in the same way:

{x₁r₁+ . . . +xₙrₙ|nε [symbol] rᵢεRᵢxᵢεX}

{r₁x₁s₁+ . . . +rₙxₙsₙ|nε [symbol] rᵢεR,sᵢεRᵢxᵢεX}.

The former is the right ideal generated by X, and the latter is the ideal generated by X. By convention, 0 is viewed as the sum of zero such terms, agreeing with the fact that the ideal of R generated by ø is {0} by the previous definition. If a left ideal I of R has a finite subset F such that I is the left ideal generated by F, then the left ideal I is said to be finitely generated. Similar terms are also applied to right ideals and two-sided ideals generated by finite subsets. In the special case where the set X is just a singleton {a} for some a in R, then the above definitions turn into the following:

Ra={ra|rεR}

aR={ar|rεR}

RaR={r₁as₁+ . . . +rₙasₙ|nε [symbol] rᵢεR,sᵢεR}.

These ideals are known as the left/right/two-sided principal ideals generated by a. It is also very common to denote the two-sided ideal generated by a as (a). If R does not have a unit, then the internal descriptions above must be modified slightly. In addition to the finite sums of products of things in X with things in R, allow the addition of n-fold sum for evaluating the performance of IEEE 802.11 network, in particularly relative to increased collisions. Here, momentum can be used to calculate the unknown velocity of a collision. Solving the momentum conservation equation for Va and the definition of the coefficient of restitution for Vb yields:

$$\frac{{m}_{s} {u}_{a} + {m}_{b} {u}_{b} - {m}_{b} {v}_{b}}{{m}_{a}} = {v}_{a}$$

$${v}_{b} = {C}_{R} ( {u}_{a} - {u}_{b} ) + {v}_{a}$$

A substitution into the first equation for Vb and then re-solving for Va gives:

$$\frac{{m}_{a} {u}_{a} + {m}_{b} {u}_{b} - {m}_{b} {C}_{R} ( {u}_{a} - {u}_{b} ) - {m}_{b} {v}_{a}}{{m}_{a}} = {v}_{a}$$

$$\frac{{m}_{a} {u}_{a} + {m}_{b} {u}_{b} + {m}_{b} {C}_{R} ( {u}_{b} - {u}_{a} )}{{m}_{a}} = {v}_{a} [ 1 + \frac{{m}_{b}}{{m}_{a}} ]$$

$$\frac{{m}_{a} {u}_{a} + {m}_{b} {u}_{b} + {m}_{b} {C}_{R} ( {u}_{b} - {u}_{a} )}{{m}_{a} + {m}_{b}} = {v}_{a}$$

A similar derivation yields the formula for Vb.

The present invention herein incorporates and extends these components and MAA, in which a plurality of transfer-to-practice tools and methods are configurable from the core architecture. A characterization of the core and processing functionalities include, matrix generation via parameterization for solution space, use of extended n-dimensional fields or aggregates whose axes correspond to determining parameters for analysis, integrated construction of topological performance visualization and iterative feedback for a priori, a posteriori instruction, performance assessment during execution, notification triggers upon variance, monitoring and reporting are herein incorporated and extend the resultant componentization and orthogonal configurations in n-dimensional arrays, in which object and path determination, strategies and scenarios for development, performance assessment, variance analysis and multiple play service provisions are generated.

As the heuristic method of MAA is extended within this invention: (A) heuristics applicable to the instruction/game mode use a method of teaching that encourages learners to discover solutions for themselves; (B) heuristics applicable to system functions, where the method of core code generated from MAA processing, reconfigures in response to the user; (C) heuristics applicable to assessment logic during operations, where the method of variance in condition is probable, but not necessarily a proof, are herein presented below.

The first two steps of a five step morphological analysis algorithm, are the designation of a problem (MAA 1, at 150) and the subsequent creation of an extensive solution space (MAA 2, at 151). As these processes relate to this invention, the designation of the problem area is a variance in pre-a priori, a priori and a posteriori instruction during performance. And the selection of mitigating parameters and relevant object matrices that might influence non-variance by the non-limiting means of visualization of causal-spatiotemporal criterion, notification and loss configured within a solution space.

There is shown at 151G, at least one of a combinatorial of determining parameters. Field parameters include: (P1a,0) single task entry by standard, indexed to type of (P2b,0) cognitive construct state correlated to instruction/game tool level, (P3c,0) type of object, (P4d,0) type of gesture hand/manipulation, (P5e,0) type of performance, (P6f,0) type of result, (P7g,0) type of loss, (P8h,0) type of monitoring, (P9i,0) type of technology convergence, (P10j,0) recordkeeping, self-monitoring.

Associable with the above listed array of parameters are at least one of a combinatorial of relative object dimension matrices including: (1,1) specific instruction by task entry (P2b,0) cognitive constructs to support a priori and a posteriori instruction execution, (2b,1) understand, compare, Demonstration, (2b,2) analyze, evaluate, Simulation practice, 2b,3) apply, create, Experiential, (2b,4) remember, Monitoring, (2b,5) meta-cognitive, Real-time monitoring and (2b,6) meta-cognitive, Recordkeeping meta-cognitive, (P3c,0) type of objects utilized in task/procedure (3a,1) static or (3c,2) dynamic, (P4d,0) hand gesture with object, (4d,1) grip, (4d,2) grasp, (P5e,0) performance, (5e, 1) inaccurate, (5e,2) inappropriate or (5e,3) untimely, (P6f,0) results (causal spaciotemporal criterion), (6f,1)health, (6f,2) environment, (6f,3) property or (6f,4) equipment; loss (P7g,0) Personal (7g,1), Financial (7g,2) Litigation (7g,3), 3 party (7g,4), monitoring (P8h,0), pre-monitoring (8h,1), real time (8h,2); technology convergence (P10j,0), broadband (91,1), telephone (9j,2), television (9j,3) and wireless (9j,4), (P10j,0), reporting, recordkeeping (1011) reporting. Those skilled in the art will appreciate while the above array of parameter dimensions represent factors that can influence instruction delivery and resource management, a further extension of the parameter dimensions will not change the scope of invention.

Upon selection of a problem space and determining parameters and matrices (i.e. 101G), the third step of the morphological analysis algorithm is to set the parameters and objects against each other, in parallel. The first extension of the MAA process, as used in the present invention is the computer-assistance or parameterization of 101G, where at least a combinatorial of at least two or all of (P1a,0-P10,j0 . . . n) and objects (1a,1-10j,2 . . . n) are configured in an n-dimensional array at 102 in FIG. 28.

The resultant configuration of the combinatorial exchange, generates (in an exemplary embodiment, 18,432) chains in a “morphological box” to facilitate visualization of interconnected relationships. An extension of this MAA step, as used within the present invention, is for analysis of cause and effect or causes that affect (cognition, performance, loss), internal consistency (cognition, performance, T-convergence), aggregated visualization of consequences (performance, results and loss) and evaluation (cognitive, performance, results) when tracking and data mining.

A second extension of this method as used in the present invention, is the generation of the configurations in transposed n-dimensional arrays, (i.e. by column and by row). Utilization of the resultant configuration vectors in the arrays, (i.e. 1,0, 2,0, 3,0 . . . n) and morphological derivatives, (i.e. tas, con, obj . . . n) generate a reconfigurable core of interoperable machine/assembly language. The interoperability of this language combined with the transposed arrays, provide a further embodiment for preferred encryption.

A further advantage of the text-to-image system architecture included in the cognitive challenge is the transferability for multi-lingual application, as illustrated in FIG. 00, where the command word may be easily translated into the desired language. A further support in an exemplary embodiment for a multi-lingual application is the development menu (i.e. authoring tool) where the single task entry may automatically adjust to a right or left entry as, required by a user. The same multi-lingual transferability can be utilized in an exemplary design menu as illustrated in FIG. 6.

In contrast to MAA processing, which often selectively determines chains or configurations. One embodiment of this invention is to extend the aforementioned MAA processing method, in which the generation of configurations indexed by the accurate sequence ordering of an instruction, transforms into a plurality of configurations of variant ordering, in transposition n-dimensional arrays.

Another embodiment within the present invention is to, (1) store all the configurations in a matrix (i.e. density, impact, morphological box) which are used to create object and path determinations for the system and (2) to retain the configurations in the path set order generated during the parameterization step. To obviate bias, (i.e. a limiting of the generated MAA during construction of all phenomenon, that is sometimes caused by a single indexing process), is provided for, in the system's iterative feedback loops (hereafter memory buffers 212), at (a) instruction, (b) practice, (c) performance (d) variance (e) notification, (e) re-try (f) retrain (g) re-practice (h) n-performance after retraining and (i) n-fault notification, illustrated in FIG. 1D, at steps 317,318,319,320,321,407, 409, 504, 513,514, 608, 611, 802, 805, 806, 807, 905, 906, 1104, 1107,1108.

Further, the generated configurations, hereafter referred to as a path set, contain primitives, hereafter referred to as the system micro level, whose axes correspond to the various determining (P1a,0-P10j,0 . . . n) and objects (P1a,1-P10j,2 . . . n), hereafter operated and referred to as the core. The path sets and primitives within the vector-based core, facilitate the generation of object and path determination for strategies and scenario development, to thereby provide for topological performance mapping with performance assessment, probable analysis and date mining (by means of n-dimensional array 3), by means of n-dimensional aggregates whose axes correspond to P1a,0-P10j,2, and multiple play service provision for signal communication by means of a transposition n-dimension array 2.

A further embodiment of the present invention, is the mapping of all primitives on a determined (i.e. accepted) behavior as represented by the task instruction 1a,1. Herein, this establishes a consistency in which determined and variant spaciotemporal criterion (i.e. event) are identified and acted upon.

A further processing as applied, in the present invention, in which each partition within the path set, has a nonzero value where (P1a,0-P10j,0 . . . n) and objects (P1a,1-P10j,2 . . . n), are weighted by assessed gravity as compared to the distance from P axes (P1a, P2b, P3c, P4d, P5e, P6f, P7g, P8h, P9i, P10j), of the correct performance of an instruction (a zero value) While set thresholds are required for real-time utility, the aforementioned determinations provide core default values.

The morphological analysis processing step in the present invention, where partitioned vectors are determined by the dimension of time, is extended by critical chain method (CCM) in a fifth embodiment. For those with skill in the art, CCM is based upon both predetermined time and resource dependencies, where the required duration time for each task is computed to occur in half or (0.50) less time.

Further processing to include, animation and simulation is linked to vectors in each path set at 5e,1, 5e,2, 5e,3, incorporating the dimension of time, extended by the critical chain method (CCM): CCM is based upon both predetermined time and resource dependencies, where the required duration time for each task is computed to occur in half or (0.50) less time and further utilized for uncertainty computations. Thus, during CCM assessment, computation of the user's performance, by time duration, is calculated at completing the task in less than or equal to half the time (≦0.50) pre-assigned during development, or (0.050 for the default value) and computed with the appropriate performance score and or combined with the determined array of parameters and respective matrices in the compliance scheme where assigned.

For example, aggregate tracking for instruction/game tool Level 1, is determined by the correct recall and task transfer to practice knowledge assessment. As critical chain method (CCM) is determined to be the normative standard upon which timely and or inappropriate (a priori sequence) user/learner performance is assessed for Practice and Experiential levels. The CCM algorithm is used to determine instruction transfer duration based upon both time and resource dependencies, continuous monitoring of the user/learner performance, resource loss and tracking of key and non-significant actions within the instruction transfer and performance scenario. In addition, CCM enables future stochastic predictions. Deviations from the normative order of the a priori path set, results in untimely performance and a lower aggregate. New steps not in the critical chain are determined to be inappropriate and also result in a lower aggregate.

In contrast, the inverse of correct procedure and task steps are combined in an impact matrix to generate incorrect scenarios. User/learner performance contrary to normative path set, are incorrect and cause reduction in the user/learner aggregate score. While qualitative assessment (e.g. probable compliant or noncompliant) of consequences are presented to the user/learner for comparison, checking and critique against normative standard representation, all inappropriate (5e,1), untimely (5e,2) and incorrect (5e,3) performance results (6f,1, 6f,2, 6f,3, 6f,4) in consequences that are correlated with resource loss (7g,1, 7g,2, 7g, 3, 7g,4).

A fourth morphological analysis processing step, is the construction of graphically represented topological performance charts to enhance visualization. For those with skill in the art, a topological performance chart can be a diagram displaying detailed information or “a map to navigate by”. As it pertains to this invention both formats are utilized. In particular, field maps 2b,5, indexed in particularly to P5e,0, P8h,0, P9i,0, can serve as maps to navigate by, prior to a instruction as illustrated in FIG. 11, or as a display after user performance as illustrated in FIGS. 10A and 10B. Further, use of topological performance displays herein, are the “lanes” of swimlanes in the RMK 31, as an aggregate presentation of performance, results and loss, after user performance.

A further extension of the aforementioned MA processing method, herein integrates and extends the graphical representation of topological performance via overlays in P3c,0, and P4d,0 mapped to consequence P7g,0, visualization in orthogonal presentations of instruction/game tool levels P2b,0 reporting P10j,0 and monitoring P8h,0 operation applications linked to the transposition n-dimensional arrays and morphological box, to thereby provide for signal communication with devices and peripherals. Where the region of convergence (ROC) of X(s) is a strip in the s plane defined

x(t)=e−α|t|.

There are three possible ROCs where:

1. R{s}>2

2. −1<R{s}<2

3. <R{s}<−1

and where the maximum error is defined

$$erf ( x ) \approx sgn ( x ) \sqrt{1 - exp ( - {x}^{2} \frac{4 / π + {ax}^{2}}{1 + {ax}^{2}} )}$$

$$where$$

$$a = \frac{8 ( π - 3 )}{3 π ( 4 - π )} \approx 0.140012 .$$

The fifth morphological analysis processing step, is the execution of all solutions generated from MA. As it pertains to this invention, the visualization of desired transfer to practice, is facilitated by multimedia and multimodal means, in which an instruction/game tool, modules for reporting and self-monitoring operation, customization module and attachable instruction/game tool are reconfigured from a core architecture. Here, the interoperability of the primitives are indexed to corresponding vectors in the modeled space.

Referring to FIG. 6, at 160, where further morphological analysis intent for realization of a solution space, is the graphic development of the combinations of the path sets into required scenarios. The visualizations can be represented as: scientific animations and simulations or real-time interaction. Scientific animation is used to describe a more technically based presentation whereby objects and environments are properly and consistently scaled and trajectories and velocities are based on the laws of physics and the appropriate equations of motion. Simulations, also based on the laws of physics, contain specific underlying equations that can predict an outcome by linking the region of convergence (ROC) vector coordinates within the modules within the n-dimension fields to vector coordinates in topological performance frames within the instruction/game tool and subsequent image replay in monitoring, real-time monitoring and record-keeping applications to signal communication.

Those with skill in the art will recognize, the current capability of graphic modeling, simulation and outsourcing practices that are employed to provide efficient yet effective graphic representation development. Vector-based modeling tools such as Autodesk Maya and Blender are used to integrate, by means of their orthogonal formatting, subsets and primitives of the path set at level design. Interoperability of the transposed n-dimension arrays and matrices, are maximized by means of the orthogonal format of modeling programs where each dimension set of single task entry, is “reconfigured” within the core. Here, frontal views are integrated with Demonstration levels at 2b,1, side and frontal views are linked with Simulation practice levels at 2b,2, perspective views are linked with Experiential levels at 2b,3, aerial or field map views are linked with Monitoring 2b4, and Real-time monitoring levels at 2b,5 and frontal, side and inverse frontal views are linked with Record-keeping levels at 2b,6.

The resultant core architecture is the framework for generation of transfer-to-practice tools. Common to the illustrated modules is the execution and intersystem sub-routines. Here, all instruction/game tools initiate sub-routines that access the RMK30 at 32, as mapped to 2b,1, 2b,2 using the bilateral LaPlace transform defined

$${x}^{∞} ( t ) ↔ X {( s )}^{∞} = {\int }_{- ∞} x ( t ) ↔ X ( s ) = {\int }_{- ∞} x ( t ) e$$

embodiment, many variations and modifications will become apparent to those skilled in the art upon reading the present application. It is therefore the intention that the appended claims be interpreted as broadly as possible in view of the prior art to include all such variations and modifications.

What is claimed:

1. A connector assemblage for use with a plurality of electrochemical assemblies, the assemblage comprising:
an energy source;
a substrate;
a joining composition.

2. The connector assemblage of claim 1, wherein the energy source further comprising a solar cell having a first electrochemical composition.

3. The connector assemblage of claim 1, wherein the solar cell having a first electrochemical composition is incorporated in a pliable package within the substrate.

4. The connector assemblage of claim 3, wherein the pliable package comprises conductor and circuitry defined therein.

5. The connector assemblage of claim 1, relative to the dermal superstrate having a melanin molecular composition.

6. The connector assemblage of claim 1, wherein the joining composition is conformed to the substrate for conformational joining to the dermal superstrate relative to the dermal superstrate having a melanin molecular composition of at least carbon, hydrogen, oxygen, nitrogen and alternating single and double bonds.

7. The connector assemblage of claim 1, wherein the joining composition is conformed to the substrate for conformational joining to a dermal superstrate relative to the dermal superstrate not having a melanin molecular composition.

8. An connector assemblage process comprising:
assembling a pliable package, wherein the pliable package comprising interconnections and an energy source having a first electrochemical assembly within a silicon substrate having a second electrochemical assembly;
assembling a joining composition having a third electrochemical assembly in which a first conformation backs to the silicon substrate and a second conformation interconnects to a melanin molecular composition; and
organizing the first electrochemical assembly and the second electrochemical assembly and the third electrochemical assembly so as to enable an adherence or reversing the adherence between the third electrochemical assembly backed to the second electrochemical assembly via the first electrochemical assembly.

9. The connector assemblage of claim 9, wherein the connector assemblage is conformational for a touch electronic device wherein the superstrate of the touch electronic device has one non-matching connector assemblage.

10. The connector assemblage of claim 10, wherein the touch electric device is tablet computer 12.

11. A connector assemblage method for electrochemical integration instruction management, the method comprising:
incorporating an instructional game integrated with operations training and execution within a compliance lifecycle; and
using a touch electronic device and a connector assemblage where both the touch electronic device and the connector assemblage together are conformational for a dermal communication.
